(19) United States
(12) Patent Application Publication
(10) Pub. No.: US 2025/0208060 A1
(43) Pub. Date: Jun. 26, 2025

(54) METHODS, APPARATUS, AND ARTICLES OF MANUFACTURE TO DETECT TRANSPARENT FLUX WITH VISIBLE LIGHT

(71) Applicant: Intel Corporation, Santa Clara, CA (US)

(72) Inventors: Fatemeh Rahimi, Gilbert, AZ (US); Andrew Nicholas Contes, Phoenix, AZ (US); Cesar Gustavo Castro Munoz, Chandler, AZ (US); Xiao Lu, Chandler, AZ (US); Chase Williams Challe, Gilbert, AZ (US); Madhuparna Roy, Arlington, TX (US)

(21) Appl. No.: 18/395,064

(22) Filed: Dec. 22, 2023

(51) Int. Cl. G01N 21/95; G01N 21/552; G01N 21/88; H01L 21/66

(52) U.S. Cl. CPC G01N 21/9501; G01N 21/552; H01L 22/24; G01N 2021/8854

(57) ABSTRACT

Systems, apparatus, articles of manufacture, and methods are disclosed to detect transparent flux with visible light. An example apparatus includes interface circuitry to communicate with an image sensor and programmable circuitry to at least one of instantiate or execute machine-readable instructions. Additionally, the example programmable circuitry is to cause the image sensor to capture reflected light off of a substrate, the reflected light being visible. The example programmable circuitry is also to, based on a level of attenuation of the reflected light relative to projected light projected onto the substrate, determine at least one of a presence or a property of transparent flux on the substrate.

### FIELD OF THE DISCLOSURE

This disclosure relates generally to semiconductors and, more particularly, to methods, apparatus, and articles of manufacture to detect transparent flux with visible light.

### BACKGROUND

Flux is a chemical agent that is used in metal joining as a cleaning agent, a flowing agent, and/or a purifying agent. Flux includes an acid and, in some examples, one or more solids in the acid. Flux can perform more than one function at a time. For example, flux is used in electronics manufacturing to facilitate soldering by removing oxidation from metals to be soldered, sealing surfaces of the metals from air to prevent further oxidation, and improving wetting characteristics of liquid solder (e.g., the ability of the liquid solder to maintain contact with the surfaces of the metals). Flux can be characterized by properties of the flux such as activity, corrosivity, cleanability, residue tack or tackiness, volatility, viscosity, flammability, conductivity, and solid content.

### BRIEF DESCRIPTION OF THE DRAWINGS

FIG. 1 illustrates an example environment in which example optical inspection circuitry detects clear flux on an example substrate.

FIG. 2 is a block diagram of an example implementation of the optical inspection circuitry of FIG. 1.

FIG. 3 is an example graphical user interface (GUI) that may be used to interface with the optical inspection circuitry of FIGS. 1 and/or 2.

FIG. 4A is a graphical illustration depicting example first absorbances of example clear flux.

FIG. 4B is a graphical illustration depicting example first transmissions of example clear flux.

FIG. 4C is a graphical illustration depicting an example second absorbance of example clear flux.

FIG. 4D is a graphical illustration depicting an example second transmission of example clear flux.

FIG. 5 is a graphical illustration depicting differences in attenuation of visible light depending on the amount of clear flux on an example substrate.

FIG. 6 is a graphical illustration depicting example attenuation signatures of substrates including different amounts of clear flux.

FIG. 7 is a graphical illustration depicting example first clear flux detection as disclosed herein.

FIG. 8 is a graphical illustration depicting example second clear flux detection as disclosed herein.

FIG. 9 is a graphical illustration depicting example third clear flux detection as disclosed herein.

FIG. 10 is a flowchart representative of example machine-readable instructions and/or example operations that may be executed, instantiated, and/or performed by example programmable circuitry to implement the optical inspection circuitry of FIG. 2.

FIG. 11 is a block diagram of an example processing platform including programmable circuitry structured to execute, instantiate, and/or perform the example machine-readable instructions and/or perform the example operations of FIG. 10 to implement the optical inspection circuitry of FIG. 2.

FIG. 12 is a block diagram of an example implementation of the programmable circuitry of FIG. 11.

FIG. 13 is a block diagram of another example implementation of the programmable circuitry of FIG. 11.

FIG. 14 is a block diagram of an example software/firmware/instructions distribution platform (e.g., one or more servers) to distribute software, instructions, and/or firmware (e.g., corresponding to the example machine-readable instructions of FIG. 10) to client devices associated with end users and/or consumers (e.g., for license, sale, and/or use), retailers (e.g., for sale, re-sale, license, and/or sub-license), and/or original equipment manufacturers (OEMs) (e.g., for inclusion in products to be distributed to, for example, retailers and/or to other end users such as direct buy customers).

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

Flux can be characterized by properties of the flux. Properties of flux include activity, corrosivity, cleanability, tackiness, volatility, viscosity, flammability, conductivity, and solid content. Activity of flux refers to the ability of the flux to dissolve existing oxides on a metal surface and to promote wetting with solder. Corrosivity of flux refers to the ability of the flux and/or residue of the flux to promote corrosion. Cleanability of flux refers to the difficulty of removing the flux and/or residue of the flux after a soldering operation. Tackiness of flux refers to how quickly an adhesive bond forms between the flux and a metal surface. Volatility of flux refers to how easily the flux will vaporize. Viscosity of flux refers to the resistance of the flux to flow. Flammability of flux refers to how quickly the flux will catch fire. Conductivity of flux refers to the ease at which an electric charge can pass through the flux. Solid content of a flux refers to the percentage of solid material in the flux.

Flux is used to remove oxides (e.g., tin oxide (SnO), nickel oxide (NiO), etc.) from the surface of solder pads, solder balls, and/or copper pillars. Additionally, flux tackiness assists with anchoring solder balls, semiconductor dies, and/or patch substrates in place during conveyance (e.g., movement of semiconductor components between manufacturing stages). In electronics manufacturing, flux is usually applied to surfaces at elevated temperatures. There are many different types of flux such as rosin flux, no-clean flux, and aqueous flux.

Rosin flux is based on a natural rosin derived from pine tar. For example, pine tar resin is dissolved in a solvent and distilled to yield a clear, water-white rosin used in rosin flux. To produce rosin flux, the clear rosin is dissolved in a solvent, such as isopropyl alcohol. Rosin flux is a translucent or opaque fluid that is colored (e.g., a brownish or a tan fluid that is translucent or opaque). Rosin flux may include a percentage of solid material.

As used herein, a transparent material refers to a material having the property of transmitting light through the material without appreciable scattering of the light so that an object lying beyond the material can be seen clearly. In some examples, a transparent material may include one or more solids suspended in the transparent material. Transparent and clear are used interchangeably herein. As used herein, a translucent material refers to a material having the property of transmitting and diffusing light so that an object beyond the material cannot be seen clearly. In some examples, a translucent material may include one or more solids suspended in the translucent material. As used herein, an opaque material refers to a material having the property of blocking the passage of light so that an object beyond the material cannot be seen. In some examples, an opaque material may include one or more solids suspended in the opaque material.

No-clean flux can be made with natural rosin or synthetic resins. If made with natural rosin, no-clean flux utilizes natural gum rosin at a much lower concentration than rosin flux. If made with synthetic resins, no-clean flux utilizes a synthetic resin that imparts desired properties to the no-clean flux. No-clean fluxes are referred to as no-clean because no-clean fluxes usually leave little to no residue behind after soldering operations, as compared to rosin flux. Aqueous flux is made with water-soluble resins. As such, residue from aqueous flux remaining after soldering can be removed using a water rinse. Some aqueous fluxes are water-based solutions. Thus, alcohol-based flux solutions need not be used with aqueous flux.

Clear flux is a type of flux that can increase process margins and/or enhance yield. Clear flux is transparent and may not include solid material. However, the transparent nature of clear flux, the lack of contrasting color between clear flux and a surface on which clear flux is applied, and the tackiness of clear flux have increased the difficulty of detecting clear flux with automated optical inspection systems. For example, automated optical inspection systems use digital image processing techniques to render measurement and inspection results in semiconductor manufacturing. Two-dimensional image acquisition utilizes contrasting colors between an object in an image and a background of the image. Additionally, three-dimensional image acquisition utilizes laser triangulation techniques to analyze solid objects.

As such, processing signals reflected from transparent fluids such as clear flux is difficult in automated optical inspection systems. Additionally, clear flux may not include solid material. As such, it is difficult for automated optical inspection systems to detect the presence of clear flux that does not include solid material. Thus, without improved automated optical inspection systems, using clear flux can increase the risk of departing from manufacturing processes. Techniques to increase process margins and/or enhance yield utilize large scale formic acid ovens and/or plasma treatment chambers instead of clear flux. However, such techniques are monetarily expensive and require a large footprint in a manufacturing facility. Additionally, without flux there is an increased risk that semiconductor components may move during conveyance (e.g., due to the lack of tackiness provided by flux).

Examples disclosed herein include clear flux detection. Methods, apparatus, and articles of manufacture disclosed herein utilize visible range image sensors (e.g., visible range optical cameras such as line-scan cameras) to detect clear flux. For example, examples disclosed herein model clear flux as a natural passive optical attenuator and determine a step-variable response of clear flux to quantify an attenuation rate of visible light that reflects off of a substrate and through clear flux as a function of the amount of clear flux on the substrate. As such, examples disclosed herein detect clear flux based on attenuation of visible light despite the lack of contrasting color and solid material in clear flux. Accordingly, examples disclosed herein improve increase process margins and/or enhance yield without significantly increasing cost (e.g., as compared to other techniques).

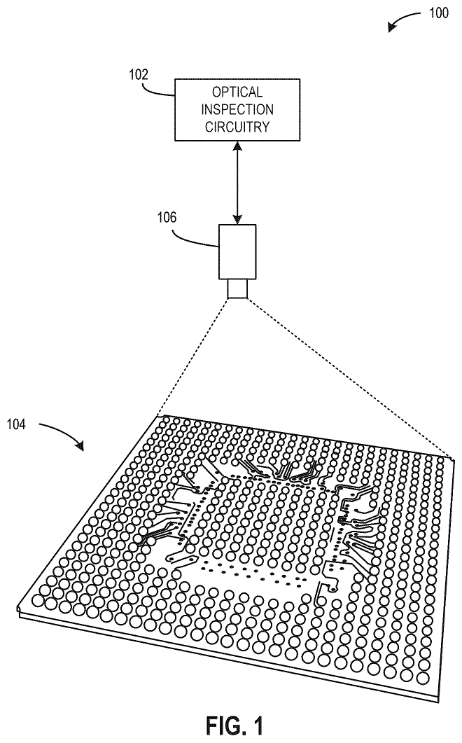

FIG. 1 illustrates an example environment 100 in which example optical inspection circuitry 102 detects clear flux on an example substrate 104. For example, the substrate 104 corresponds to at least one of a semiconductor die or an integrated circuit package substrate. In the example of FIG. 1, the environment 100 corresponds to a manufacturing environment for manufacturing electronic devices. In additional or alternative examples, the environment 100 corresponds to another environment.

In the illustrated example of FIG. 1, the substrate 104 includes a ball grid array (BGA). A BGA is a grid of interconnection pins that are coupled to the leads of the substrate 104. During electronics manufacturing, clear flux is applied to the surface of the substrate 104 to facilitate soldering the BGA to one or more surfaces. To ensure that clear flux has been applied to the surface of the substrate 104 to satisfy an electronics manufacturing process, the optical inspection circuitry 102 causes an example image capturing system 106 to scan the substrate 104 with visible light.

For example, the image capturing system 106 includes an example light source to project visible light onto the substrate 104 and an example image sensor to capture visible light reflected off of the substrate 104. In some examples, the image capturing system 106 is implemented by an example image sensor and an example light source is implemented separately from the image capturing system 106. In examples disclosed herein, visible light includes a wavelength between 360 and 750 nanometers. As such, visible light is visible to an average human observer.

In the illustrated example of FIG. 1, the image capturing system 106 is implemented by a line-scan image sensor. For example, a line-scan image sensor, such as a laser-based image sensor, utilizes a line (e.g., a 1 by N line) of pixels to capture an image (e.g., a one-dimensional (1D) image) of an object and scans the object to generate a two-dimensional (2D) image. To scan the object, equipment moves the object with respect to the line-scan image sensor and/or moves the line-scan image sensor with respect to the object. In general, a line-scan image sensor includes a dynamic range that is greater than that of an area-scan image sensor (e.g., an image sensor that uses an N by M grid of pixels to capture an image). As such, line-scan image sensors generally provide greater resolution than area-scan image sensors.

In the illustrated example of FIG. 1, the optical inspection circuitry 102 causes the image capturing system 106 to capture visible light reflected off of the substrate 104. Additionally, the optical inspection circuitry 102 determines a level of attenuation of the reflected visible light relative to visible light that was projected onto the substrate 104. For example, the optical inspection circuitry 102 determines the level of attenuation based on the signal-to-noise ratio (SNR) of the reflected visible light. By utilizing a line-scan image sensor (e.g., a laser-based line-scan image sensor and/or a laser-based line-scan camera) to capture reflected visible light, the optical inspection circuitry 102 detects attenuated signals more efficiently.

As disclosed herein, there is a difference between signal attenuation levels from light beams reflected from a bare surface and signal attenuation levels from light beams reflected from a surface covered with clear flux. For example, clear flux functions as a natural passive optical attenuator. As such, examples disclosed herein produce repeatable attenuation signatures for different amounts of clear flux disposed on a surface, similar to a step-variable optical attenuator. Accordingly, by monitoring of the attenuation levels of reflected light from the substrate 104, the optical inspection circuitry 102 confirms whether clear flux is disposed on the substrate 104 to satisfy an electronics manufacturing process.

In the illustrated example of FIG. 1, the optical inspection circuitry 102 stores one or more attenuation signatures (e.g., boundary conditions) for different amounts of clear flux disposed on a surface. For example, the optical inspection circuitry 102 stores an attenuation signature for a bare surface (e.g., a surface including no clear flux), one or attenuation signatures for a surface including a threshold amount of clear flux at one or more temperatures, an attenuation signature for a surface including two times the threshold amount of clear flux, an attenuation signature for a surface including three times the threshold amount of clear flux, etc. By comparing the level of attenuation of the reflected visible light to the one or more attenuation signatures, the optical inspection circuitry 102 determines a property of clear flux that may be on the substrate 104. For example, the optical inspection circuitry 102 determines whether clear flux is present on the substrate 104, a height of clear flux disposed on the substrate 104, a volume of clear flux disposed on the substrate 104, etc.

In the illustrated example of FIG. 1, the optical inspection circuitry 102 compares the property of clear flux (e.g., as measured based on image analysis of reflected visible light captured by the image capturing system 106) to a threshold value for the property. For example, if the property of clear flux is the presence of clear flux, the optical inspection circuitry 102 determines whether it was intended for clear flux to be disposed on the substrate 104. If clear flux was intended to be disposed on the substrate 104 and the optical inspection circuitry 102 determines that clear flux is disposed on the substrate 104, then the optical inspection circuitry 102 determines that the property satisfies the threshold value for the property (e.g., the substrate 104 passes inspection). If clear flux was intended to be disposed on the substrate 104 and the optical inspection circuitry 102 determines that clear flux is not disposed on the substrate 104, then the optical inspection circuitry 102 determines that the property does not satisfy the threshold value for the property (e.g., the substrate 104 fails inspection).

Additionally or alternatively, if the property of clear flux is the height (e.g., thickness) of clear flux disposed on the substrate 104, the optical inspection circuitry 102 determines whether the height of clear flux disposed on the substrate 104 satisfies (e.g., is equal to or exceeds) a threshold height of clear flux to be disposed on the substrate 104. If the optical inspection circuitry 102 determines that the height of clear flux disposed on the substrate 104 satisfies the threshold height of clear flux, then the optical inspection circuitry 102 determines that the property satisfies the threshold value for the property (e.g., the substrate 104 passes inspection). If the optical inspection circuitry 102 determines that the height of clear flux disposed on the substrate 104 does not meet (e.g., is less than) the threshold height of clear flux, then the optical inspection circuitry 102 determines that the property does not satisfy the threshold value for the property (e.g., the substrate 104 fails inspection).

In some examples, if the property of clear flux is the volume of clear flux disposed on the substrate 104, the optical inspection circuitry 102 determines whether the volume of clear flux disposed on the substrate 104 satisfies (e.g., is equal to or exceeds) a threshold volume of clear flux to be disposed on the substrate 104. If the optical inspection circuitry 102 determines that the volume of clear flux disposed on the substrate 104 satisfies the threshold volume of clear flux, then the optical inspection circuitry 102 determines that the property satisfies the threshold value for the property (e.g., the substrate 104 passes inspection). If the optical inspection circuitry 102 determines that the volume of clear flux disposed on the substrate 104 does not meet (e.g., is less than) the threshold volume of clear flux, then the optical inspection circuitry 102 determines that the property does not satisfy the threshold value for the property (e.g., the substrate 104 fails inspection).

In the illustrated example of FIG. 1, if the optical inspection circuitry 102 determines that the substrate 104 passed inspection, the optical inspection circuitry 102 flags the substrate 104 as including the threshold amount of clear flux. As such, equipment can determine that the substrate 104 is ready for the next stage of a manufacturing process. In this manner, if the optical inspection circuitry 102 determines that the substrate 104 passed inspection, the optical inspection circuitry 102 causes equipment to process the substrate 104 at the next stage of a manufacturing process.

Additionally or alternatively, if the optical inspection circuitry 102 determines that the substrate 104 failed inspection, the optical inspection circuitry 102 flags the substrate 104 for reprocessing to adjust an amount of clear flux on the substrate 104. As such, equipment can determine that the substrate 104 is to be reprocessed by a preceding stage of a manufacturing process (e.g., is to have clear flux reapplied to the substrate 104). In this manner, if the optical inspection circuitry 102 determines that the substrate 104 fails inspection, the optical inspection circuitry 102 causes equipment to reprocess the substrate 104 at a preceding stage of a manufacturing process (e.g., to reapply clear flux to the substrate 104).

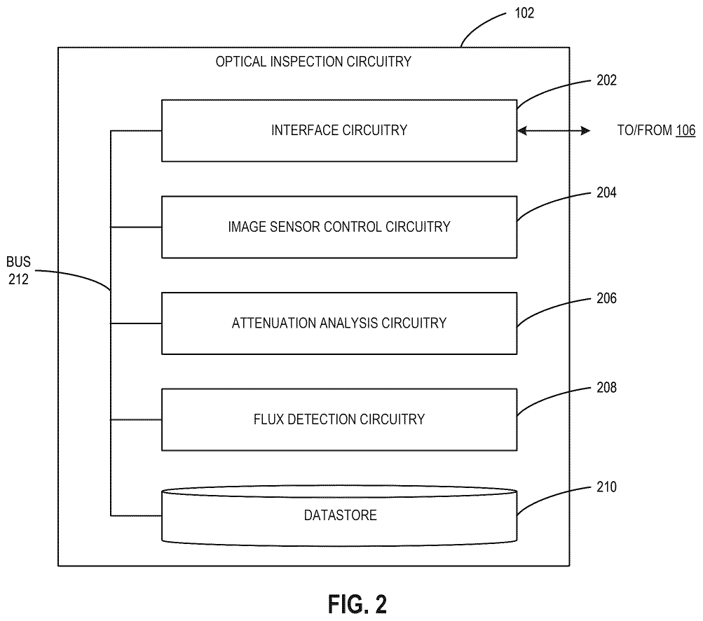

FIG. 2 is a block diagram of an example implementation of the optical inspection circuitry 102 of FIG. 1. In the example of FIG. 2, the optical inspection circuitry 102 includes example interface circuitry 202, example image sensor control circuitry 204, example attenuation analysis circuitry 206, example flux detection circuitry 208, and an example datastore 210. In the example of FIG. 2, the interface circuitry 202, the image sensor control circuitry 204, the attenuation analysis circuitry 206, the flux detection circuitry 208, and the datastore 210 are coupled via an example bus 212. The example bus 212 may be implemented using any suitable wired and/or wireless communication. In some examples, the bus 212 includes software, machine-readable instructions, and/or communication protocols by which information is communicated among the interface circuitry 202, the image sensor control circuitry 204, the attenuation analysis circuitry 206, the flux detection circuitry 208, and/or the datastore 210.

In the illustrated example of FIG. 2, the optical inspection circuitry 102 may be instantiated (e.g., creating an instance of, bring into being for any length of time, materialize, implement, etc.) by programmable circuitry such as a Central Processor Unit (CPU) executing first instructions. Additionally or alternatively, the optical inspection circuitry 102 of FIG. 2 may be instantiated (e.g., creating an instance of, bring into being for any length of time, materialize, implement, etc.) by (i) an Application Specific Integrated Circuit (ASIC) and/or (ii) a Field Programmable Gate Array (FPGA) structured and/or configured in response to execution of second instructions to perform operations corresponding to the first instructions. It should be understood that some or all of the circuitry of FIG. 2 may, thus, be instantiated at the same or different times. Some or all of the circuitry of FIG. 2 may be instantiated, for example, in one or more threads executing concurrently on hardware and/or in series on hardware. Moreover, in some examples, some or all of the circuitry of FIG. 2 may be implemented by microprocessor circuitry executing instructions and/or FPGA circuitry performing operations to implement one or more virtual machines and/or containers.

In the illustrated example of FIG. 2, the interface circuitry 202 is in communication with the image capturing system 106. For example, the interface circuitry 202 transmits an instruction from the image sensor control circuitry 204 to a light source (e.g., a light source of the image capturing system 106) to cause the light source to project visible light onto a substrate (e.g., the substrate 104 of FIG. 1). Additionally or alternatively, the interface circuitry 202 transmits an instruction from the image sensor control circuitry 204 to an image sensor (e.g., a laser-based line-scan image sensor of the image capturing system 106) to cause the image sensor to capture visible light reflected off of the substrate (e.g., the substrate 104 of FIG. 1).

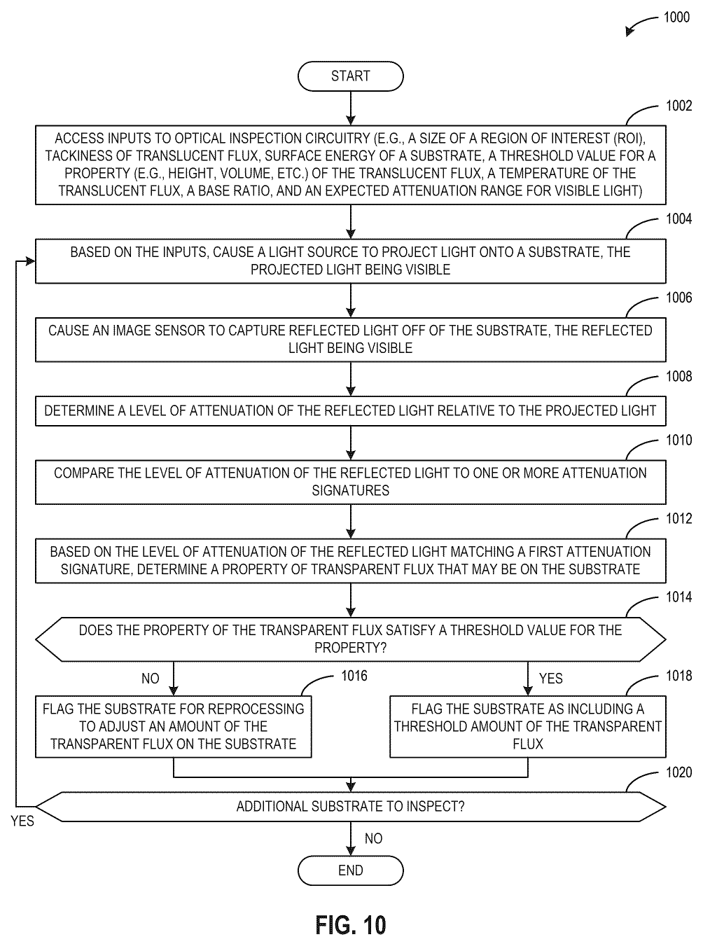

In some examples, the interface circuitry 202 transmits an instruction from the image sensor control circuitry 204 to the light source and/or the image sensor to move the light source and/or the image sensor (e.g., control a position of the image capturing system 106 in the environment 100 of FIG. 1, to move the image capturing system 106 along one or more tracks, etc.). Additionally or alternatively, the interface circuitry 202 transmits an instruction from the image sensor control circuitry 204 to equipment to move the substrate (e.g., control a position of equipment on which the substrate 104 of FIG. 1 is situated, move equipment on which the substrate 104 of FIG. 1 is situated along one or more tracks, etc.). In the example of FIG. 2, the interface circuitry 202 is in communication with one or more input/output (I/O) devices to facilitate user input to the optical inspection circuitry 102. In some examples, the interface circuitry 202 is instantiated by programmable circuitry executing interface instructions and/or configured to perform operations such as those represented by the flowchart of FIG. 10.

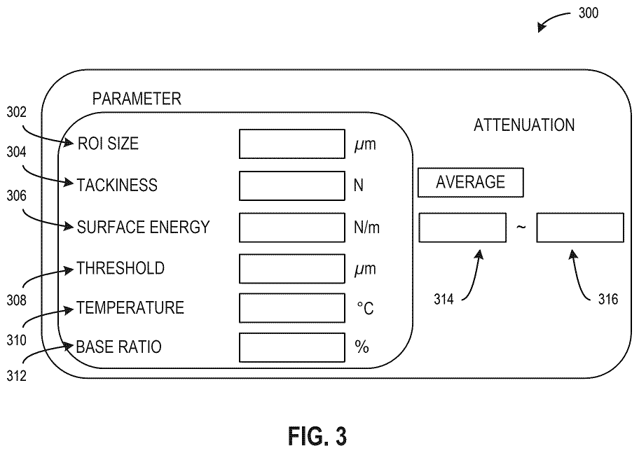

FIG. 3 is an example graphical user interface (GUI) 300 that may be used to interface with the optical inspection circuitry 102 of FIGS. 1 and/or 2. In the example of FIG. 3, the GUI 300 includes an example first input field 302 through which a user of the optical inspection circuitry 102 can input a size of a region of interest (ROI) on a substrate to be inspected by the optical inspection circuitry 102. For example, the size of the ROI may be specified in micrometers (μm).

Additionally, the GUI 300 includes an example second input field 304 through which a user of the optical inspection circuitry 102 can input a tackiness of clear flux that is expected to be on a substrate. For example, the tackiness of clear flux may be specified in Newtons (N). In the example of FIG. 3, the GUI 300 also includes an example third input field 306 through which a user of the optical inspection circuitry 102 can input a surface energy of a substrate to be inspected by the optical inspection circuitry 102. For example, surface energy is a measure of excess energy at the surface of a material compared to the bulk region of the material. In the example of FIG. 3, the surface energy of a substrate may be specified in Newtons per meter (N/m). In some examples, the third input field 306 is a field through which a user of the optical inspection circuitry 102 can input a surface tension of flux that is to be disposed on a substrate.

In the illustrated example of FIG. 3, the GUI 300 includes an example fourth input field 308 through which a user of the optical inspection circuitry 102 can input a threshold amount of clear flux expected to be in a ROI of a substrate. For example, the threshold amount of clear flux may be specified in micrometers (μm). In the example of FIG. 3, the GUI 300 includes an example fifth input field 310 through which a user of the optical inspection circuitry 102 can input a temperature of an object (e.g., a temperature of clear flux on a substrate, a temperature of the substrate on which the clear flux is expected to be present, etc.). For example, the temperature may be specified in degrees Celsius (° C.).

In the illustrated example of FIG. 3, the GUI 300 includes an example sixth input field 312 through which a user of the optical inspection circuitry 102 can input a base ratio for a substrate. For example, a base ratio is a ratio defining the base from which the optical inspection circuitry 102 is to measure an amount of clear flux on a substrate. In the example of FIG. 3, the base ratio may be specified in micrometers (μm) and/or as a percent of the base of a substrate. Additionally, the GUI 300 includes an example seventh field 314 and an example eighth field 316 through which a user of the optical inspection circuitry 102 can input a range of attenuation expected for visible light reflected off of a substrate. For example, the range of attenuation may be specified as a percentage.

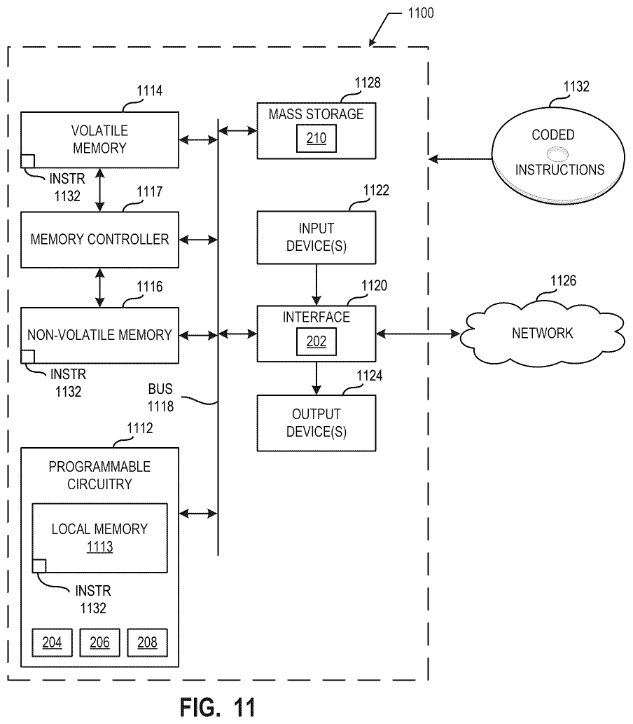

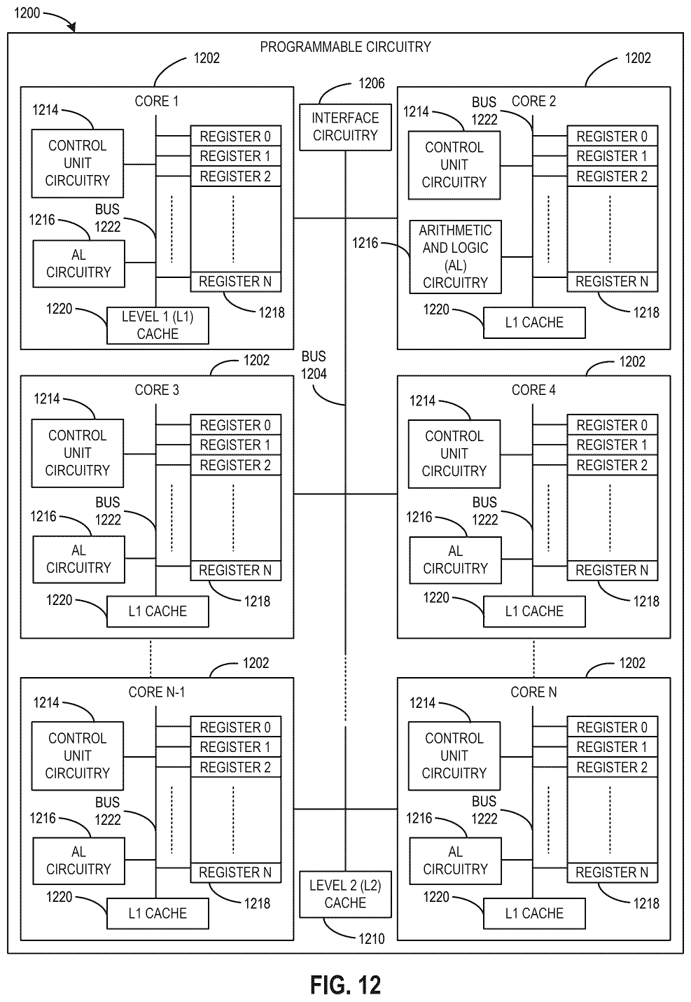

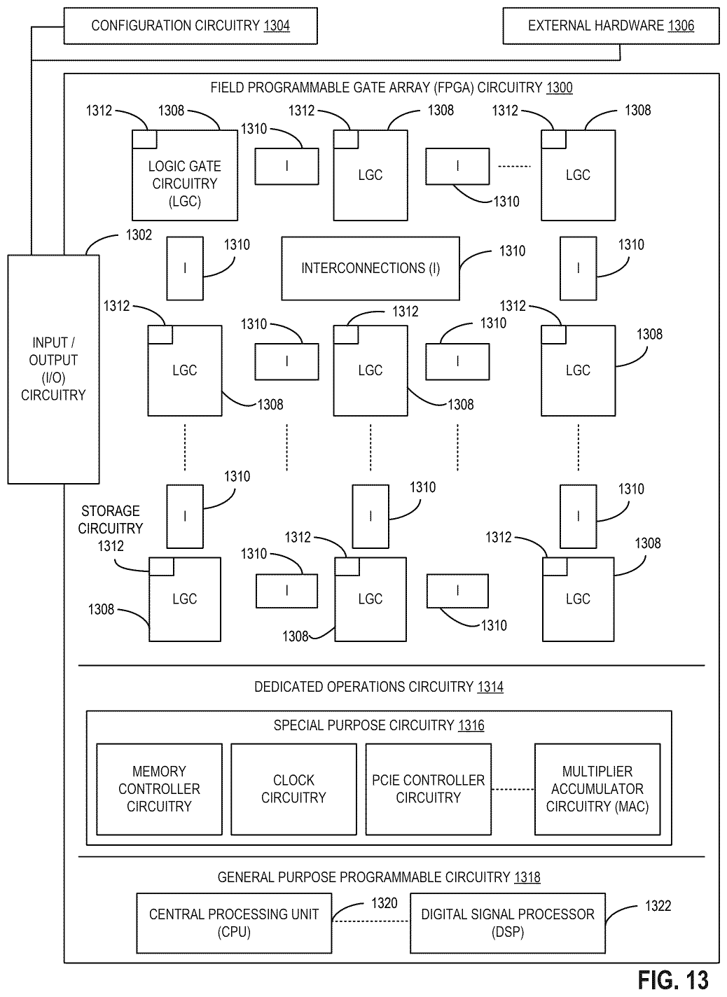

Returning to the example of FIG. 2, in some examples, the optical inspection circuitry 102 includes means for interfacing with a device. For example, the means for interfacing may be implemented by the interface circuitry 202. In some examples, the interface circuitry 202 may be instantiated by programmable circuitry such as the example programmable circuitry 1112 of FIG. 11. For instance, the interface circuitry 202 may be instantiated by the example microprocessor 1200 of FIG. 12 executing machine-executable instructions such as those implemented by at least block 1002 of FIG. 10. In some examples, the interface circuitry 202 may be instantiated by hardware logic circuitry, which may be implemented by an ASIC, XPU, or the FPGA circuitry 1300 of FIG. 13 configured and/or structured to perform operations corresponding to the machine-readable instructions. Additionally or alternatively, the interface circuitry 202 may be instantiated by any other combination of hardware, software, and/or firmware. For example, the interface circuitry 202 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine-readable instructions and/or to perform some or all of the operations corresponding to the machine-readable instructions without executing software or firmware, but other structures are likewise appropriate.

In the illustrated example of FIG. 2, the image sensor control circuitry 204 controls a light source and/or an image sensor (e.g., the image capturing system 106). In some examples, based on one or more inputs (e.g., made through the GUI 300 of FIG. 3), the image sensor control circuitry 204 causes a light source to project visible light onto a substrate (e.g., the substrate 104 of FIG. 1). For example, the image sensor control circuitry 204 causes a light source to project visible light onto a ROI of the substrate based on the one or more inputs. Additionally or alternatively, the image sensor control circuitry 204 causes an image sensor to capture visible light reflected off of the substrate (e.g., the substrate 104 of FIG. 1). In some examples, the image sensor control circuitry 204 is instantiated by programmable circuitry executing image sensor controlling instructions and/or configured to perform operations such as those represented by the flowchart of FIG. 10.

In some examples, the optical inspection circuitry 102 includes means for controlling an image sensor. For example, the means for controlling may be implemented by the image sensor control circuitry 204. In some examples, the image sensor control circuitry 204 may be instantiated by programmable circuitry such as the example programmable circuitry 1112 of FIG. 11. For instance, the image sensor control circuitry 204 may be instantiated by the example microprocessor 1200 of FIG. 12 executing machine-executable instructions such as those implemented by at least blocks 1004, 1006, and 1020 of FIG. 10. In some examples, the image sensor control circuitry 204 may be instantiated by hardware logic circuitry, which may be implemented by an ASIC, XPU, or the FPGA circuitry 1300 of FIG. 13 configured and/or structured to perform operations corresponding to the machine-readable instructions. Additionally or alternatively, the image sensor control circuitry 204 may be instantiated by any other combination of hardware, software, and/or firmware. For example, the image sensor control circuitry 204 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine-readable instructions and/or to perform some or all of the operations corresponding to the machine-readable instructions without executing software or firmware, but other structures are likewise appropriate.

In the illustrated example of FIG. 2, the attenuation analysis circuitry 206 determines a level of attenuation of reflected visible light relative to projected visible light. In the example of FIG. 2, the attenuation analysis circuitry 206 determines the level of attenuation of reflected visible light based on the SNR of the reflected visible light. For example, the attenuation analysis circuitry 206 determines the SNR of light according to Equation 1 below.

$$S N R = \frac{{P}_{LIGHT}}{{P}_{B A C K G R O U N D}} \qquad Equation 1$$

In the example of Equation 1, P_{LIGHT} represents the power of light (e.g., reflected visible light, projected visible light, etc.) and P_{BACKGROUND} represents the power of background noise. For example, background noise is a preset value based on (a) noise caused by an image sensor used to capture reflected light and (b) noise caused by an environment in which the optical inspection circuitry 102 operates. Additionally, for example, power of light is measured in decibels (dB). In some examples, power of light is a measure of the intensity of the light (e.g., the intensity of reflected visible light). For example, the attenuation analysis circuitry 206 determines the intensity of reflected visible light according to Equation 2 below.

$$I = {I}_{0} {e}^{- μ x} \qquad Equation 2$$

In the example of Equation 2, I represents the intensity of reflected light, measured in the number of lumens falling in an area, and I₀ represents the intensity of projected light, measured in the number of lumens falling in an area. In the example of Equation 2, x represents a distance travelled by the projected light and the reflected light, measured in micrometers (μm), and u represents an attenuation coefficient of clear flux, measured in inverse micrometers (μm⁻¹). To determine the level of attenuation of reflected visible light based on Equation 1 and/or Equation 2, the attenuation analysis circuitry 206 compares (e.g., determines a delta between) the SNR of the reflected visible light and the SNR of projected visible light.

For example, the attenuation analysis circuitry 206 computes the percentage difference between the SNR of the reflected visible light and the SNR of the projected visible light. In some examples, the attenuation analysis circuitry 206 computes the absolute difference between the SNR of the reflected visible light and the SNR of the projected visible light. Additionally or alternatively, the attenuation analysis circuitry 206 compares (e.g., determines a delta between) the SNR of the reflected visible light and the SNR of the projected visible light in any other manner. In some examples, the attenuation analysis circuitry 206 is instantiated by programmable circuitry executing attenuation analysis instructions and/or configured to perform operations such as those represented by the flowchart of FIG. 10.

In some examples, the attenuation analysis circuitry 206 includes means for analyzing attenuation of light. For example, the means for analyzing may be implemented by the attenuation analysis circuitry 206. In some examples, the attenuation analysis circuitry 206 may be instantiated by programmable circuitry such as the example programmable circuitry 1112 of FIG. 11. For instance, the attenuation analysis circuitry 206 may be instantiated by the example microprocessor 1200 of FIG. 12 executing machine-executable instructions such as those implemented by at least block 1008 of FIG. 10. In some examples, the attenuation analysis circuitry 206 may be instantiated by hardware logic circuitry, which may be implemented by an ASIC, XPU, or the FPGA circuitry 1300 of FIG. 13 configured and/or structured to perform operations corresponding to the machine-readable instructions. Additionally or alternatively, the attenuation analysis circuitry 206 may be instantiated by any other combination of hardware, software, and/or firmware. For example, the attenuation analysis circuitry 206 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine-readable instructions and/or to perform some or all of the operations corresponding to the machine-readable instructions without executing software or firmware, but other structures are likewise appropriate.

In the illustrated example of FIG. 2, the flux detection circuitry 208 determines one or more of the presence of clear flux on a substrate or at least one property of clear flux that may be present on the substrate. For example, the flux detection circuitry 208 accesses one or more attenuation signatures from the datastore 210 and compares a level of the attenuation of reflected light to the one or more attenuation signatures. Based on the level of attenuation of the reflected light matching one of the one or more attenuation signatures, the flux detection circuitry 208 determines one or more of the presence of clear flux on a substrate or at least one property of clear flux that may be present on the substrate.

For example, the one or more attenuation signatures include an attenuation signature for a bare surface (e.g., a surface including no clear flux), one or more attenuation signatures for a surface including a threshold amount of clear flux at one or more temperatures, an attenuation signature for a surface including two times the threshold amount of clear flux, an attenuation signature for a surface including three times the threshold amount of clear flux, etc. As such, by comparing a level of attenuation of reflected light to the one or more attenuation signatures, the flux detection circuitry 208 determines whether clear flux is present on a substrate, a height of clear flux disposed on the substrate, a volume of clear flux disposed on the substrate, etc.

In the illustrated example of FIG. 2, the flux detection circuitry 208 compares a property of clear flux that may be on a substrate to a threshold value for the property. Based on the flux detection circuitry 208 determining that the property satisfies the threshold value for the property, the flux detection circuitry 208 flags the substrate as including a threshold amount of clear flux. Based on the flux detection circuitry 208 determining that the property does not satisfy the threshold value for the property, the flux detection circuitry 208 flags the substrate for reprocessing to adjust an amount of clear flux on the substrate. In some examples, the flux detection circuitry 208 compares the property of clear flux to two or more threshold values.

For example, the flux detection circuitry 208 compares the property of clear flux to an upper threshold value and a lower threshold value. In this manner, if the flux detection circuitry 208 determines that the property of clear flux satisfies one of the upper threshold value or the lower threshold value but does not satisfy the other of the upper threshold value or the lower threshold value, then the flux detection circuitry 208 can detect a problem with a manufacturing process. For example, the flux detection circuitry 208 determines that the property of clear flux satisfies the lower threshold value (e.g., exceeds the lower threshold value) but does not satisfy the upper threshold value (e.g., exceeds the upper threshold value), then the flux detection circuitry 208 determines that too much clear flux has been disposed on the substrate which is indicative of a problem with a manufacturing process. In some examples, the flux detection circuitry 208 is instantiated by programmable circuitry executing flux detection instructions and/or configured to perform operations such as those represented by the flowchart of FIG. 10.

In some examples, the optical inspection circuitry 102 includes means for detecting flux. For example, the means for detecting may be implemented by the flux detection circuitry 208. In some examples, the flux detection circuitry 208 may be instantiated by programmable circuitry such as the example programmable circuitry 1112 of FIG. 11. For instance, the flux detection circuitry 208 may be instantiated by the example microprocessor 1200 of FIG. 12 executing machine-executable instructions such as those implemented by at least blocks 1010, 1012, 1014, 1016, and 1018 of FIG. 10. In some examples, the flux detection circuitry 208 may be instantiated by hardware logic circuitry, which may be implemented by an ASIC, XPU, or the FPGA circuitry 1300 of FIG. 13 configured and/or structured to perform operations corresponding to the machine-readable instructions. Additionally or alternatively, the flux detection circuitry 208 may be instantiated by any other combination of hardware, software, and/or firmware. For example, the flux detection circuitry 208 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine-readable instructions and/or to perform some or all of the operations corresponding to the machine-readable instructions without executing software or firmware, but other structures are likewise appropriate.

In the illustrated example of FIG. 2, the datastore 210 records (e.g., stores) data. For example, the datastore 210 records data representative of one or more attenuation signatures, data representative of one or more intensities of light (e.g., reflected light, projected light, etc.), data representative of one or more inputs, data representative of a threshold value for a property of clear flux, and/or other data. The datastore 210 may be implemented by a volatile memory (e.g., a Synchronous Dynamic Random Access Memory (SDRAM), Dynamic Random Access Memory (DRAM), RAMBUS Dynamic Random Access Memory (RDRAM), etc.) and/or a non-volatile memory (e.g., flash memory). The datastore 210 may additionally or alternatively be implemented by one or more double data rate (DDR) memories, such as DDR, DDR2, DDR3, DDR4, DDR5, mobile DDR (mDDR), DDR SDRAM, etc.

In the illustrated example of FIG. 2, the datastore 210 may additionally or alternatively be implemented by one or more mass storage devices such as hard disk drive(s) (HDD(s)), compact disk (CD) drive(s), digital versatile disk (DVD) drive(s), solid-state disk (SSD) drive(s), Secure Digital (SD) card(s), CompactFlash (CF) card(s), etc. While in the illustrated example the datastore 210 is illustrated as a single datastore, the datastore 210 may be implemented by any number and/or type(s) of datastores. Furthermore, the data stored in the datastore 210 may be in any data format such as, for example, binary data, comma delimited data, tab delimited data, structured query language (SQL) structures, etc.

While an example manner of implementing the optical inspection circuitry 102 of FIG. 1 is illustrated in FIG. 2, one or more of the elements, processes, and/or devices illustrated in FIG. 2 may be combined, divided, re-arranged, omitted, eliminated, and/or implemented in any other way. Further, the example interface circuitry 202, the example image sensor control circuitry 204, the example attenuation analysis circuitry 206, the example flux detection circuitry 208, the example datastore 210, and/or, more generally, the example optical inspection circuitry 102 of FIG. 2, may be implemented by hardware alone or by hardware in combination with software and/or firmware. Thus, for example, any of the example interface circuitry 202, the example image sensor control circuitry 204, the example attenuation analysis circuitry 206, the example flux detection circuitry 208, the example datastore 210, and/or, more generally, the example optical inspection circuitry 102 of FIG. 2, could be implemented by programmable circuitry in combination with machine-readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), and/or field programmable logic device(s) (FPLD(s)) such as FPGAs. Further still, the example optical inspection circuitry 102 of FIG. 2 may include one or more elements, processes, and/or devices in addition to, or instead of, those illustrated in FIG. 2, and/or may include more than one of any or all of the illustrated elements, processes, and devices.

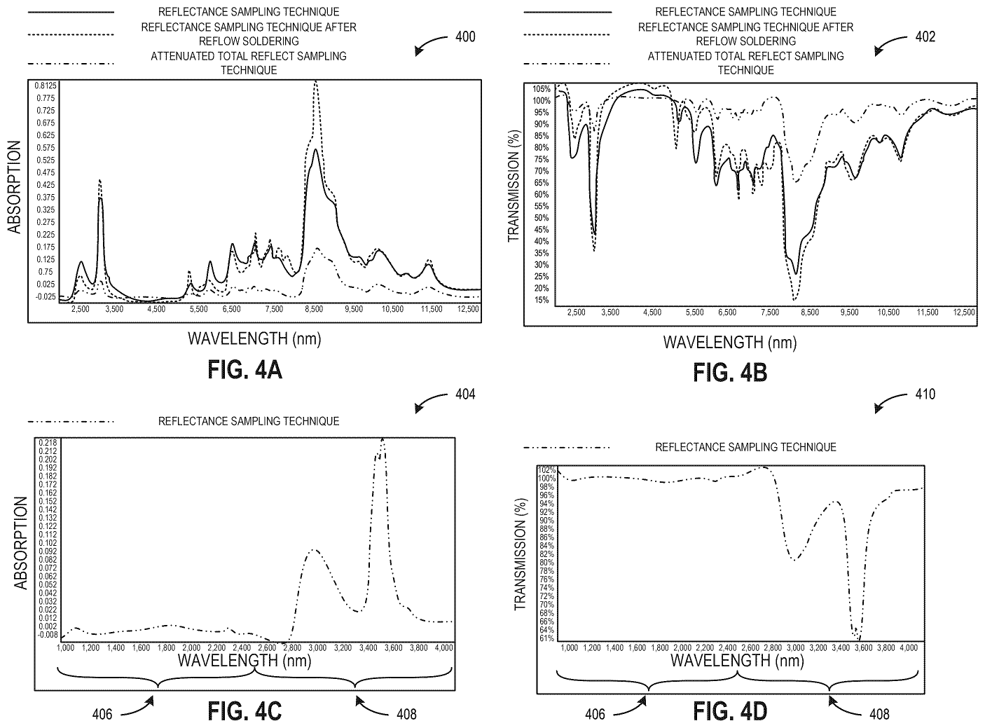

FIG. 4A is a graphical illustration 400 depicting example first absorbances of example clear flux. In examples disclosed herein, absorbance is a measure of how much light is absorbed by a material as the light travels through the material. In the example of FIG. 4A, the graphical illustration 400 depicts example absorbance of the clear flux measured via an attenuated total reflection (ATR) sampling technique, example absorbance of the clear flux measured via a reflectance (e.g., spectral reflectance, diffuse reflectance, etc.) sampling technique, and example absorbance of the clear flux measured after reflow soldering via a reflectance sampling technique. In the example of FIG. 4A, the example clear flux is 6352i flux provided by Senju Metal Industry Co., Ltd.

FIG. 4B is a graphical illustration 402 depicting example first transmissions of example clear flux. In examples disclosed herein, transmission or transmittance is a measure of the ability of a material to transmit light through the material. In the example of FIG. 4B, the graphical illustration 402 depicts example transmittance of the clear flux measured via an ATR sampling technique, example transmittance of the clear flux measured via a reflectance sampling technique, and example transmittance of the clear flux measured after reflow soldering via a reflectance sampling technique. In the example of FIG. 4B, the example clear flux is 6352i flux provided by Senju Metal Industry Co., Ltd.

FIG. 4C is a graphical illustration 404 depicting an example second absorbance of example clear flux. In examples disclosed herein, absorbance is a measure of how much light is absorbed by a material as the light travels through the material. In the example of FIG. 4C, the graphical illustration 404 depicts example absorbance of the clear flux measured via a reflectance sampling technique. Additionally, the graphical illustration 404 depicts an example near infrared (NIR) region 406 of the electromagnetic spectrum that ranges from wavelengths of 1,000 nanometers (nm) to 2,500 nm. The graphical illustration 404 also depicts an example partial mid infrared (partial mid-IR) region 408 of the electromagnetic spectrum that ranges from wavelengths of 2,500 nm to 4,000 nm. In the example of FIG. 4C, the example clear flux is 6352i flux provided by Senju Metal Industry Co., Ltd.

FIG. 4D is a graphical illustration 410 depicting an example second transmission of example clear flux. In examples disclosed herein, transmission or transmittance is a measure of the ability of a material to transmit light through the material. In the example of FIG. 4D, the graphical illustration 410 depicts example transmittance of the clear flux measured via a reflectance sampling technique. Additionally, the graphical illustration 410 depicts the example NIR region 406 of the electromagnetic spectrum and the example partial mid-IR region 408 of the electromagnetic spectrum. In the example of FIG. 4D, the example clear flux is 6352i flux provided by Senju Metal Industry Co., Ltd.

FIGS. 4A, 4B, 4C, and 4D (collectively referred to as FIG. 4), illustrate the absorbance and transmittance spectra of, for example, clear flux. As illustrated in FIG. 4, clear flux has little to no absorbance in the visible range of the electromagnetic spectrum. Thus, clear flux does not absorb incident light and attenuation is the main contributor to the changes measured in signal content in each image sensor pixel.

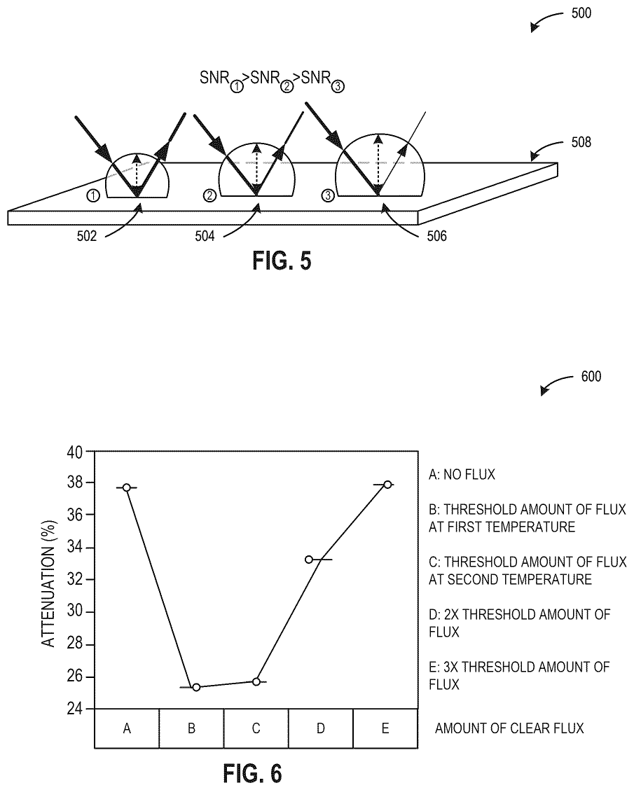

FIG. 5 is a graphical illustration 500 depicting differences in attenuation of visible light depending on the amount of clear flux on an example substrate. For example, the graphical illustration 500 depicts example first clear flux 502 (denoted with a “1”) having a first height, example second clear flux 504 (denoted with a “2”) having a second height, and example third clear flux 506 (denoted with a “3”) having a third height. In the example of FIG. 5, the first height of the first clear flux 502 is less than the second height of the second clear flux 504. Additionally, the second height of the second clear flux 504 is less than the third height of the third clear flux 506.

In the illustrated example of FIG. 5, as light beams pass through the first clear flux 502, the second clear flux 504, and the third clear flux 506 and reflects off of an example substrate 508, the amount of attenuation of the light beams differs. For example, a light beam is illustrated by a line passing through clear flux (e.g., the first clear flux 502, the second clear flux 504, the third clear flux 506, etc.). In the example of FIG. 5, arrows on a line illustrate the direction of travel of a light beam and the thickness of a line illustrates the intensity of a light beam. For example, clear flux is a natural passive optical attenuator where the amount of attenuation depends on the amount of clear flux through which a light beam passes.

Thus, when a light beam passes through the second clear flux 504, the light beam is more attenuated than when a light beam passes through the first clear flux 502 (e.g., the SNR of light passing through the second clear flux 504 is less than the SNR of light passing through the first clear flux 502). Additionally, when a light beam passes through the third clear flux 506, the light beam is more attenuated than when a light beam passes through the second clear flux 504 (e.g., the SNR of light passing through the third clear flux 506 is less than the SNR of light passing through the second clear flux 504). As such, by monitoring signal attenuation rate after a light beam penetrates through clear flux and reflects from a substrate (e.g., the substrate 508) on which the clear flux is dispensed and/or sprayed, the optical inspection circuitry 102 can determine an amount of clear flux on the substrate.

For example, signal attenuation levels vary between a bare substrate and a substrate covered with flux. Thus, by using machine learning, the optical inspection circuitry 102 can be trained to identify one or more ROIs on a substrate where clear flux is expected to be present. Additionally, a user can define (e.g., via the GUI 300 of FIG. 3) one or more thresholds (e.g., boundary conditions) for the amount of flux expected to be present in an ROI. For example, a user can define that an amount of clear flux between 3 and 5 micrometers in height is expected to be present in an ROI. In some examples, a user can define (e.g., via the GUI 300 of FIG. 3) one or more threshold (e.g., boundary conditions) for attenuated signal content. For example, a user can define that, based on an amount of clear flux expected to be present in an ROI, a light beam is expected to be attenuated by 50-70%. Accordingly, by comparing a level of attenuation of light reflected off of a substrate in an ROI to one or more thresholds, the optical inspection circuitry 102 can determine an amount of clear flux present in the ROI. As such, the optical inspection circuitry 102 can determine whether a sufficient, an insufficient, or an excessive amount of clear flux is present on the substrate.

In some examples, the optical inspection circuitry 102 can utilize signal attenuation to determine properties of a substrate. For example, if the optical inspection circuitry 102 detects different signal attenuation rates for a known amount of dispensed flux on two different substrates, the optical inspection circuitry 102 determines that the two substrates have different surface energies. Additionally or alternatively, the optical inspection circuitry 102 can utilize signal attenuation to determine additional or alternative properties of flux. For example, if the optical inspection circuitry 102 detects different attenuation rates at the beginning and/or the end of processing of a lot of substrates, the optical inspection circuitry 102 determines that the flux temperature may have changed during processing of the lot and consequently tackiness of the flux may differ between substrates of the lot.

In some examples, the optical inspection circuitry 102 can utilize signal attenuation to determine properties of manufacturing equipment. For example, if the optical inspection circuitry 102 detects different attenuation rates in the middle of processing a lot of substrates as compared to the beginning of processing, the optical inspection circuitry 102 determines that one or more dispensing nozzles may be clogged. By detecting a variety of properties of flux, substrates, and/or equipment, the optical inspection circuitry 102 can issue alerts to cause remediation of defective conditions. As such, the optical inspection circuitry 102 improves (e.g., optimizes) the manufacturing process and increases yield.

FIG. 6 is a graphical illustration 600 depicting example attenuation signatures of substrates including different amounts of clear flux. In the example of FIG. 6, the graphical illustration 600 depicts different levels of attenuation of light when reflected after passing through different amounts of clear flux. For example, the graphical illustration 600 depicts different attenuation values (e.g., percentage attenuation) measured for a bare substrate (e.g., no flux), a substrate covered with a threshold amount of clear flux at a first temperature, a substrate covered with the threshold amount of clear flux at a second temperature, a substrate covered with two times the threshold amount of clear flux, and a substrate covered with three times the threshold amount of clear flux.

In the illustrated example of FIG. 6, the first temperature is 62° C. and the second temperature is 55° C. As illustrated in the graphical illustration 600, the attenuation signature for the threshold amount of clear flux at the first temperature is different than the attenuation signature for no flux and/or the attenuation signature for an excess amount of clear flux. In this manner, clear flux acts as a natural passive optical attenuator similar to a step-variable optical attenuator. Empirical data supports the precision of utilizing signal attenuation to detect clear flux over time. For example, the optical inspection circuitry 102 can perform at least 30 consecutive inspections of clear flux on a substrate over the time the substrate is being processed.

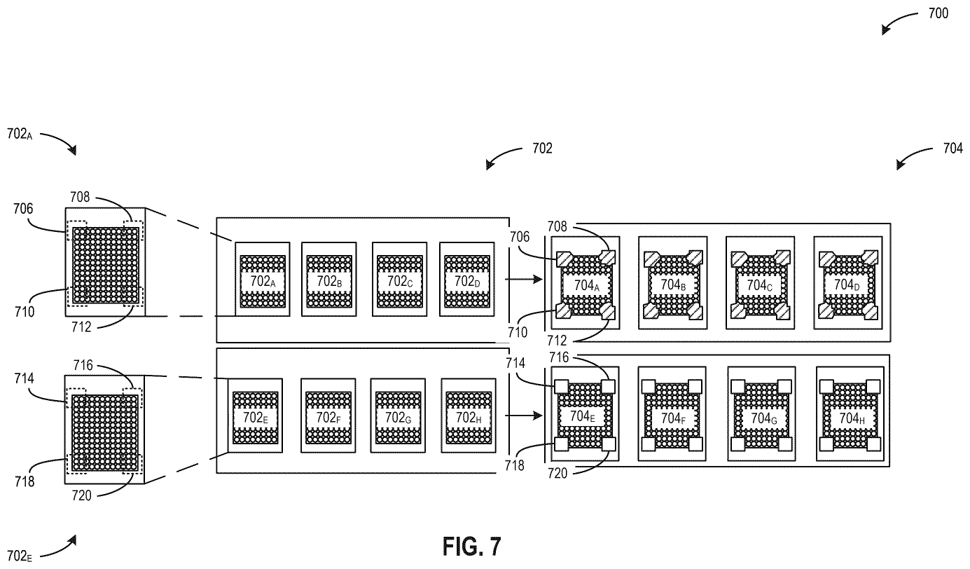

FIG. 7 is a graphical illustration 700 depicting example first clear flux detection as disclosed herein. For example, the graphical illustration 700 depicts example substrates 702 including a first group of substrates that have been sprayed with clear flux and a second group of substrates that have been sprayed with clear flux. However, one or more of the substrates 702 may have different surface energies which may result in the clear flux failing to remain on the one or more of the substrates 702. In the example of FIG. 7, the graphical illustration 700 also depicts example results 704 of inspecting the substrates 702 with the optical inspection circuitry 102 of FIGS. 1 and/or 2.

In the illustrated example of FIG. 7, the first group of the substrates 702 includes an example first substrate 702A, an example second substrate 702B, an example third substrate 702c, and an example fourth substrate 702p. Additionally, the second group of the substrates 702 includes an example fifth substrate 702E, an example sixth substrate 702F, an example seventh substrate 702G, and an example eighth substrate 702H. In the example of FIG. 7, each of the substrates 702 includes one or more ROIs to be inspected by the optical inspection circuitry 102. For example, the first substrate 702A includes an example first ROI 706, an example second ROI 708, an example third ROI 710, and an example fourth ROI 712. Additionally, the fifth substrate 702E includes an example fifth ROI 714, an example sixth ROI 716, an example seventh ROI 718, and an example eighth ROI 720.

In the illustrated example of FIG. 7, the results 704 include an example first result 704A of an inspection of the first substrate 702A with the optical inspection circuitry 102. Additionally, the results 704 include an example second result 704B of an inspection of the second substrate 702B with the optical inspection circuitry 102. The results 704 also include an example third result 704c of an inspection of the third substrate 702c with the optical inspection circuitry 102. In the example of FIG. 7, the results 704 include an example fourth result 704p of an inspection of the fourth substrate 702D with the optical inspection circuitry 102.

In the illustrated example of FIG. 7, the results 704 include an example fifth result 704E of an inspection of the fifth substrate 702E with the optical inspection circuitry 102. Additionally, the results 704 include an example sixth result 704F of an inspection of the sixth substrate 702F with the optical inspection circuitry 102. The results 704 also include an example seventh result 704G of an inspection of the seventh substrate 702G with the optical inspection circuitry 102. In the example of FIG. 7, the results 704 include an example eighth result 704H of an inspection of the eighth substrate 702H with the optical inspection circuitry 102.

In the illustrated example of FIG. 7, the first ROI 706, the second ROI 708, the third ROI 710, and the fourth ROI 712 are filled in the first result 704A to illustrate that clear flux is not present on the first substrate 702A. Additionally, the second result 704B, the third result 704c, and the fourth result 704D are similar to the first result 704A. In the example of FIG. 7, the fifth ROI 714, the sixth ROI 716, the seventh ROI 718, and the eighth ROI 720 are not filled in the fifth result 704E to illustrate that a threshold amount of clear flux is present on the fifth substrate 702E. Additionally, the sixth result 704F, the seventh result 704G, and the eighth result 704H are similar to the fifth result 704E.

In the illustrated example of FIG. 7, the substrates 702 were sprayed with clear flux under similar conditions by equipment. As such, the presence of clear flux on the second group of the substrates 702 but the absence of clear flux on the first group of the substrates 702 is indicative that there may be a difference in surface energy between the first group of the substrates 702 and the second group of the substrates 702. Thus, by detecting the presence of clear flux on the second group of the substrates 702 but the absence of clear flux on the first group of the substrates 702, the optical inspection circuitry 102 detects a difference in surface energies between the first group of the substrates 702 and the second group of the substrates 702 which is indicative of an issue with a manufacturing process.

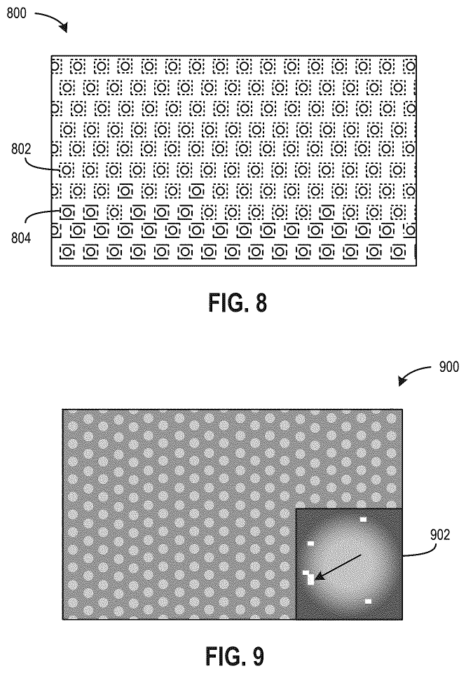

FIG. 8 is a graphical illustration 800 depicting example second clear flux detection as disclosed herein. For example, example attenuation-based detection disclosed herein allows for detection of the presence and/or absence of sprayed flux. In the example of FIG. 8, the graphical illustration 800 depicts a BGA on an interposer that has been sprayed with clear flux and inspected by the optical inspection circuitry 102 for verification prior to patch attachment.

In the illustrated example of FIG. 8, the graphical illustration 800 depicts that the optical inspection circuitry 102 detected solder balls outlined in a first dash pattern (e.g., an example first solder ball 802) as not being covered by a threshold amount of flux while solder balls in a second dash pattern (e.g., an example second solder ball 804) as covered by the threshold amount of flux. For example, the larger dynamic range of line-scan image sensors utilized by the optical inspection circuitry 102 allows the optical inspection circuitry 102 to quantify attenuation rates in received signals from sprayed flux material (e.g., that operates as a natural optical attenuator).

FIG. 9 is a graphical illustration 900 depicting example third clear flux detection as disclosed herein. For example, the graphical illustration 900 depicts a BGA on an interposer that has been sprayed with clear flux and inspected by the optical inspection circuitry 102 for verification prior to patch attachment. In the example of FIG. 9, the graphical illustration 900 includes an example inset 902 depicting a magnified image of one of the solder balls of the BGA. By analyzing signal attenuations, the optical inspection circuitry 102 can identify the sporadic dots around the solder ball. Additionally, by identifying the sporadic dots around the solder ball, the optical inspection circuitry 102 can determine the presence of clear flux covering the solder ball.

As illustrated in FIGS. 8 and 9, attenuation-based detection disclosed herein allows for detection of the presence and/or absence of sprayed flux. Semiconductor dies are monetarily expensive. As such, by detecting the presence and/or absence of clear flux on semiconductor dies (e.g., before patch attachment), examples disclosed herein improve yield and reduce monetary loss.

For example, usually a human technician inspects a BGA in a setup unit using an optical microscope to confirm clear flux coverage before lot processing. In such an example, a human technician may sample a substrate before lot processing to check if clear flux was properly applied. However, it is infeasible for a human technician to check all the substrates in a lot before processing as such checking would render manufacturing impractical due to extended duration. As such, relying on checking performed by human technicians subjects a manufacturing process to the risk of insufficient to no flux coverage (e.g., in the event of clogged dispense nozzles, unexpected change of temperature and/or surface energy, etc.).

Furthermore, setup units used by human technicians usually undergo a cleaning process after each use which can change the surface energy of the setup unit. Thus, human inspection of a substrate on a setup unit may be misleading as the surface energy of the setup unit may not be the same as the surface energy of substrates during lot processing. Accordingly, by inspecting substrates during lot processing, example attenuation-based detection disclosed herein avoids the risk of surface energy differences and can inspect all substrates in a lot. Thus, example attenuation-based detection disclosed herein provides verification of flux spray coverage for each substrate in a lot (e.g., provides in-line inspection and verification).

A flowchart representative of example machine-readable instructions, which may be executed by programmable circuitry (e.g., cause programmable circuitry) to implement and/or instantiate the optical inspection circuitry 102 of FIG. 2 and/or representative of example operations which may be performed by programmable circuitry to implement and/or instantiate the optical inspection circuitry 102 of FIG. 2, are shown in FIG. 10. The machine-readable instructions may be one or more executable programs or portion(s) of one or more executable programs for execution by programmable circuitry such as the programmable circuitry 1112 shown in the example programmable circuitry platform 1100 discussed below in connection with FIG. 11 and/or may be one or more function(s) or portion(s) of functions to be performed by the example programmable circuitry (e.g., an FPGA) discussed below in connection with FIGS. 12 and/or 13. In some examples, the machine-readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer-readable and/or machine-readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer-readable and/or machine-readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine-readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer-readable storage medium may include one or more mediums. Further, although the example program is described with reference to the flowchart illustrated in FIG. 10, many other methods of implementing the example optical inspection circuitry 102 may alternatively be used. For example, the order of execution of the blocks of the flowchart(s) may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)). For example, the programmable circuitry may be a CPU and/or an FPGA located in the same package (e.g., the same integrated circuit (IC) package or in two or more separate housings), one or more processors in a single machine, multiple processors distributed across multiple servers of a server rack, multiple processors distributed across one or more server racks, etc., and/or any combination(s) thereof.

The machine-readable instructions described herein may be stored in one or more of a compressed format, an encrypted format, a fragmented format, a compiled format, an executable format, a packaged format, etc. Machine-readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, and/or produce machine-executable instructions. For example, the machine-readable instructions may be fragmented and stored on one or more storage devices, disks and/or computing devices (e.g., servers) located at the same or different locations of a network or collection of networks (e.g., in the cloud, in edge devices, etc.). The machine-readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine-readable instructions may be stored in multiple parts, which are individually compressed, encrypted, and/or stored on separate computing devices, wherein the parts when decrypted, decompressed, and/or combined form a set of computer-executable and/or machine-executable instructions that implement one or more functions and/or operations that may together form a program such as that described herein.

In another example, the machine-readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine-readable instructions may need to be configured (e.g., settings stored, data input, network addresses recorded, etc.) before the machine-readable instructions and/or the corresponding program(s) can be executed in whole or in part. Thus, machine-readable, computer-readable and/or machine-readable media, as used herein, may include instructions and/or program(s) regardless of the particular format or state of the machine-readable instructions and/or program(s).

The machine-readable instructions described herein can be represented by any past, present, or future instruction language, scripting language, programming language, etc. For example, the machine-readable instructions may be represented using any of the following languages: C, C++, Java, C#, Perl, Python, JavaScript, HyperText Markup Language (HTML), Structured Query Language (SQL), Swift, etc.

As mentioned above, the example operations of FIG. 10 may be implemented using executable instructions (e.g., computer-readable and/or machine-readable instructions) stored on one or more non-transitory computer-readable and/or machine-readable media. As used herein, the terms non-transitory computer-readable medium, non-transitory computer-readable storage medium, non-transitory machine-readable medium, and/or non-transitory machine-readable storage medium are expressly defined to include any type of computer-readable storage device and/or storage disk and to exclude propagating signals and to exclude transmission media. Examples of such non-transitory computer-readable medium, non-transitory computer-readable storage medium, non-transitory machine-readable medium, and/or non-transitory machine-readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer-readable storage device” and “non-transitory machine-readable storage device” are defined to include any physical (mechanical, magnetic and/or electrical) hardware to retain information for a time period, but to exclude propagating signals and to exclude transmission media. Examples of non-transitory computer-readable storage devices and/or non-transitory machine-readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer-readable instructions, machine-readable instructions, etc., and/or manufactured to execute computer-readable instructions, machine-readable instructions, etc.

FIG. 10 is a flowchart representative of example machine-readable instructions and/or example operations 1000 that may be executed, instantiated, and/or performed by example programmable circuitry to implement the optical inspection circuitry 102 of FIG. 2. The example machine-readable instructions and/or the example operations 1000 of FIG. 10 begin at block 1002, at which the interface circuitry 202 accesses one or more inputs to the optical inspection circuitry 102. For example, at block 1002, the interface circuitry 202 accesses a size of an ROI, a tackiness of transparent flux, a surface energy of a substrate, a threshold value for a property (e.g., height, volume, etc.) of the transparent flux, a temperature of the transparent flux, a base ratio, and an expected attenuation range for visible light.

In the illustrated example of FIG. 10, based on the one or more inputs, the image sensor control circuitry 204 causes a light source (e.g., of the image capturing system 106) to project light onto a substrate at block 1004. For example, the projected light is visible light. At block 1006, the image sensor control circuitry 204 causes an image sensor (e.g., of the image capturing system 106) to capture reflected light off of the substrate. For example, the reflected light is visible light.

In the illustrated example of FIG. 10, at block 1008, the attenuation analysis circuitry 206 determines a level of attenuation of the reflected light relative to the projected light. For example, the attenuation analysis circuitry 206 determines the level of attenuation based on the SNR of the reflected light. In some examples, the attenuation analysis circuitry 206 determines the level of attenuation of the reflected light based on Equation 1 and/or Equation 2, as described above. At block 1010, the flux detection circuitry 208 compares the level of attenuation of the reflected light to one or more attenuation signatures.

For example, the datastore 210 stores one or more attenuation signatures for different amounts of transparent flux disposed on a surface such as an attenuation signature for a bare surface (e.g., a surface including no transparent flux), one or attenuation signatures for a surface including a threshold amount of transparent flux at one or more temperatures, an attenuation signature for a surface including two times the threshold amount of transparent flux, an attenuation signature for a surface including three times the threshold amount of transparent flux, etc. Based on the level of attenuation of the reflected light matching a first attenuation signature, the flux detection circuitry 208 determines a property of transparent flux that may be on the substrate at block 1012.

For example, the flux detection circuitry 208 determines whether transparent flux is present on the substrate, a height of transparent flux disposed on the substrate, a volume of transparent flux disposed on the substrate, etc. At block 1014, the flux detection circuitry 208 determines whether the property of the transparent flux satisfies a threshold value for the property. For example, at block 1014, the flux detection circuitry 208 compares the property to a threshold value for the property. Based on (e.g., in response to) the flux detection circuitry 208 determining that the property does not satisfy the threshold value for the property (block 1014: NO), the machine-readable instructions and/or the operations 1000 proceed to block 1016.

In the illustrated example of FIG. 10, at block 1016, the flux detection circuitry 208 flags the substrate for reprocessing to adjust an amount of the transparent flux on the substrate. Based on (e.g., in response to) the flux detection circuitry 208 determining that the property satisfies the threshold value for the property (block 1014: YES), the machine-readable instructions and/or the operations 1000 proceed to block 1018. At block 1018, the flux detection circuitry 208 flags the substrate as including a threshold amount of the transparent flux.

In the illustrated example of FIG. 10, at block 1020, the image sensor control circuitry 204 determines whether there is an additional substrate to inspect. Based on (e.g., in response to) the image sensor control circuitry 204 determining that there is an additional substrate to inspect (block 1020: YES), the machine-readable instructions and/or the operations 1000 return to block 1004. Based on (e.g., in response to) the image sensor control circuitry 204 determining that there is not an additional substrate to inspect (block 1020: NO), the machine-readable instructions and/or the operations 1000 terminate.

FIG. 11 is a block diagram of an example programmable circuitry platform 1100 structured to execute and/or instantiate the example machine-readable instructions and/or the example operations of FIG. 10 to implement the optical inspection circuitry 102 of FIG. 2. The programmable circuitry platform 1100 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a digital video recorder, a personal video recorder, or any other type of computing and/or electronic device.

The programmable circuitry platform 1100 of the illustrated example includes programmable circuitry 1112. The programmable circuitry 1112 of the illustrated example is hardware. For example, the programmable circuitry 1112 can be implemented by one or more integrated circuits, logic circuits, FPGAs, microprocessors, CPUs, GPUs, DSPs, and/or microcontrollers from any desired family or manufacturer. The programmable circuitry 1112 may be implemented by one or more semiconductor based (e.g., silicon based) devices. In this example, the programmable circuitry 1112 implements the example image sensor control circuitry 204, the example attenuation analysis circuitry 206, and the example flux detection circuitry 208.

The programmable circuitry 1112 of the illustrated example includes a local memory 1113 (e.g., a cache, registers, etc.). The programmable circuitry 1112 of the illustrated example is in communication with main memory 1114, 1116, which includes a volatile memory 1114 and a non-volatile memory 1116, by a bus 1118. The volatile memory 1114 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 1116 may be implemented by flash memory and/or any other desired type of memory device. Access to the main memory 1114, 1116 of the illustrated example is controlled by a memory controller 1117. In some examples, the memory controller 1117 may be implemented by one or more integrated circuits, logic circuits, microcontrollers from any desired family or manufacturer, or any other type of circuitry to manage the flow of data going to and from the main memory 1114, 1116.

The programmable circuitry platform 1100 of the illustrated example also includes interface circuitry 1120. The interface circuitry 1120 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 1122 are connected to the interface circuitry 1120. The input device(s) 1122 permit(s) a user (e.g., a human user, a machine user, etc.) to enter data and/or commands into the programmable circuitry 1112. The input device(s) 1122 can be implemented by, for example, an audio sensor, a microphone, a camera (still or video), a keyboard, a button, a mouse, a touchscreen, a trackpad, a trackball, an isopoint device, and/or a voice recognition system.

One or more output devices 1124 are also connected to the interface circuitry 1120 of the illustrated example. The output device(s) 1124 can be implemented, for example, by a light source, display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 1120 of the illustrated example, thus, typically includes a graphics driver card, a graphics driver chip, and/or graphics processor circuitry such as a GPU.

The interface circuitry 1120 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 1126. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc. In this examples, the interface circuitry 1120 implements the example interface circuitry 202.

The programmable circuitry platform 1100 of the illustrated example also includes one or more mass storage discs or devices 1128 to store firmware, software, and/or data. Examples of such mass storage discs or devices 1128 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs. In this examples, the one or more mass storage discs or devices 1128 implement the example datastore 210.

The machine-readable instructions 1132, which may be implemented by the machine-readable instructions of FIG. 10, may be stored in the mass storage device 1128, in the volatile memory 1114, in the non-volatile memory 1116, and/or on at least one non-transitory computer-readable storage medium such as a CD or DVD which may be removable.

FIG. 12 is a block diagram of an example implementation of the programmable circuitry 1112 of FIG. 11. In this example, the programmable circuitry 1112 of FIG. 11 is implemented by a microprocessor 1200. For example, the microprocessor 1200 may be a general-purpose microprocessor (e.g., general-purpose microprocessor circuitry). The microprocessor 1200 executes some or all of the machine-readable instructions of the flowchart of FIG. 10 to effectively instantiate the circuitry of FIG. 2 as logic circuits to perform operations corresponding to those machine-readable instructions. In some such examples, the circuitry of FIG. 2 is instantiated by the hardware circuits of the microprocessor 1200 in combination with the machine-readable instructions. For example, the microprocessor 1200 may be implemented by multi-core hardware circuitry such as a CPU, a DSP, a GPU, an XPU, etc. Although it may include any number of example cores 1202 (e.g., 1 core), the microprocessor 1200 of this example is a multi-core semiconductor device including N cores. The cores 1202 of the microprocessor 1200 may operate independently or may cooperate to execute machine-readable instructions. For example, machine code corresponding to a firmware program, an embedded software program, or a software program may be executed by one of the cores 1202 or may be executed by multiple ones of the cores 1202 at the same or different times. In some examples, the machine code corresponding to the firmware program, the embedded software program, or the software program is split into threads and executed in parallel by two or more of the cores 1202. The software program may correspond to a portion or all of the machine-readable instructions and/or operations represented by the flowchart of FIG. 10.

The cores 1202 may communicate by a first example bus 1204. In some examples, the first bus 1204 may be implemented by a communication bus to effectuate communication associated with one(s) of the cores 1202. For example, the first bus 1204 may be implemented by at least one of an Inter-Integrated Circuit (I2C) bus, a Serial Peripheral Interface (SPI) bus, a PCI bus, or a PCIe bus. Additionally or alternatively, the first bus 1204 may be implemented by any other type of computing or electrical bus. The cores 1202 may obtain data, instructions, and/or signals from one or more external devices by example interface circuitry 1206. The cores 1202 may output data, instructions, and/or signals to the one or more external devices by the interface circuitry 1206. Although the cores 1202 of this example include example local memory 1220 (e.g., Level 1 (L1) cache that may be split into an L1 data cache and an L1 instruction cache), the microprocessor 1200 also includes example shared memory 1210 that may be shared by the cores (e.g., Level 2 (L2 cache)) for high-speed access to data and/or instructions. Data and/or instructions may be transferred (e.g., shared) by writing to and/or reading from the shared memory 1210. The local memory 1220 of each of the cores 1202 and the shared memory 1210 may be part of a hierarchy of storage devices including multiple levels of cache memory and the main memory (e.g., the main memory 1114, 1116 of FIG. 11). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 1202 may be referred to as a CPU, DSP, GPU, etc., or any other type of hardware circuitry. Each core 1202 includes control unit circuitry 1214, arithmetic and logic (AL) circuitry 1216 (sometimes referred to as an ALU), a plurality of registers 1218, the local memory 1220, and a second example bus 1222. Other structures may be present. For example, each core 1202 may include vector unit circuitry, single instruction multiple data (SIMD) unit circuitry, load/store unit (LSU) circuitry, branch/jump unit circuitry, floating-point unit (FPU) circuitry, etc. The control unit circuitry 1214 includes semiconductor-based circuits structured to control (e.g., coordinate) data movement within the corresponding core 1202. The AL circuitry 1216 includes semiconductor-based circuits structured to perform one or more mathematic and/or logic operations on the data within the corresponding core 1202. The AL circuitry 1216 of some examples performs integer-based operations. In other examples, the AL circuitry 1216 also performs floating-point operations. In yet other examples, the AL circuitry 1216 may include first AL circuitry that performs integer-based operations and second AL circuitry that performs floating-point operations. In some examples, the AL circuitry 1216 may be referred to as an Arithmetic Logic Unit (ALU).

The registers 1218 are semiconductor-based structures to store data and/or instructions such as results of one or more of the operations performed by the AL circuitry 1216 of the corresponding core 1202. For example, the registers 1218 may include vector register(s), SIMD register(s), general-purpose register(s), flag register(s), segment register(s), machine-specific register(s), instruction pointer register(s), control register(s), debug register(s), memory management register(s), machine check register(s), etc. The registers 1218 may be arranged in a bank as shown in FIG. 12. Alternatively, the registers 1218 may be organized in any other arrangement, format, or structure, such as by being distributed throughout the core 1202 to shorten access time. The second bus 1222 may be implemented by at least one of an I2C bus, a SPI bus, a PCI bus, or a PCIe bus.

Each core 1202 and/or, more generally, the microprocessor 1200 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 1200 is a semiconductor device fabricated to include many transistors interconnected to implement the structures described above in one or more integrated circuits (ICs) contained in one or more packages.

The microprocessor 1200 may include and/or cooperate with one or more accelerators (e.g., acceleration circuitry, hardware accelerators, etc.). In some examples, accelerators are implemented by logic circuitry to perform certain tasks more quickly and/or efficiently than can be done by a general-purpose processor. Examples of accelerators include ASICs and FPGAs such as those discussed herein. A GPU, DSP and/or other programmable device can also be an accelerator. Accelerators may be on-board the microprocessor 1200, in the same chip package as the microprocessor 1200 and/or in one or more separate packages from the microprocessor 1200.

FIG. 13 is a block diagram of another example implementation of the programmable circuitry 1112 of FIG. 11. In this example, the programmable circuitry 1112 is implemented by FPGA circuitry 1300. For example, the FPGA circuitry 1300 may be implemented by an FPGA. The FPGA circuitry 1300 can be used, for example, to perform operations that could otherwise be performed by the example microprocessor 1200 of FIG. 12 executing corresponding machine-readable instructions. However, once configured, the FPGA circuitry 1300 instantiates the operations and/or functions corresponding to the machine-readable instructions in hardware and, thus, can often execute the operations/functions faster than they could be performed by a general-purpose microprocessor executing the corresponding software.

More specifically, in contrast to the microprocessor 1200 of FIG. 12 described above (which is a general purpose device that may be programmed to execute some or all of the machine-readable instructions represented by the flowchart of FIG. 10 but whose interconnections and logic circuitry are fixed once fabricated), the FPGA circuitry 1300 of the example of FIG. 13 includes interconnections and logic circuitry that may be configured, structured, programmed, and/or interconnected in different ways after fabrication to instantiate, for example, some or all of the operations/functions corresponding to the machine-readable instructions represented by the flowchart of FIG. 10. In particular, the FPGA circuitry 1300 may be thought of as an array of logic gates, interconnections, and switches. The switches can be programmed to change how the logic gates are interconnected by the interconnections, effectively forming one or more dedicated logic circuits (unless and until the FPGA circuitry 1300 is reprogrammed). The configured logic circuits enable the logic gates to cooperate in different ways to perform different operations on data received by input circuitry. Those operations may correspond to some or all of the instructions (e.g., the software and/or firmware) represented by the flowchart of FIG. 10. As such, the FPGA circuitry 1300 may be configured and/or structured to effectively instantiate some or all of the operations/functions corresponding to the machine-readable instructions of the flowchart of FIG. 10 as dedicated logic circuits to perform the operations/functions corresponding to those software instructions in a dedicated manner analogous to an ASIC. Therefore, the FPGA circuitry 1300 may perform the operations/functions corresponding to the some or all of the machine-readable instructions of FIG. 10 faster than the general-purpose microprocessor can execute the same.

In the example of FIG. 13, the FPGA circuitry 1300 is configured and/or structured in response to being programmed (and/or reprogrammed one or more times) based on a binary file. In some examples, the binary file may be compiled and/or generated based on instructions in a hardware description language (HDL) such as Lucid, Very High Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 1300 of FIG. 13 may access and/or load the binary file to cause the FPGA circuitry 1300 of FIG. 13 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 1300 of FIG. 13 to cause configuration and/or structuring of the FPGA circuitry 1300 of FIG. 13, or portion(s) thereof.

In some examples, the binary file is compiled, generated, transformed, and/or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is compiled, generated, and/or otherwise output from the uniform software platform based on the second instructions. In some examples, the FPGA circuitry 1300 of FIG. 13 may access and/or load the binary file to cause the FPGA circuitry 1300 of FIG. 13 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 1300 of FIG. 13 to cause configuration and/or structuring of the FPGA circuitry 1300 of FIG. 13, or portion(s) thereof.

The FPGA circuitry 1300 of FIG. 13, includes example input/output (I/O) circuitry 1302 to obtain and/or output data to/from example configuration circuitry 1304 and/or external hardware 1306. For example, the configuration circuitry 1304 may be implemented by interface circuitry that may obtain a binary file, which may be implemented by a bit stream, data, and/or machine-readable instructions, to configure the FPGA circuitry 1300, or portion(s) thereof. In some such examples, the configuration circuitry 1304 may obtain the binary file from a user, a machine (e.g., hardware circuitry (e.g., programmable or dedicated circuitry) that may implement an Artificial Intelligence/Machine Learning (AI/ML) model to generate the binary file), etc., and/or any combination(s) thereof). In some examples, the external hardware 1306 may be implemented by external hardware circuitry. For example, the external hardware 1306 may be implemented by the microprocessor 1200 of FIG. 12.

The FPGA circuitry 1300 also includes an array of example logic gate circuitry 1308, a plurality of example configurable interconnections 1310, and example storage circuitry 1312. The logic gate circuitry 1308 and the configurable interconnections 1310 are configurable to instantiate one or more operations/functions that may correspond to at least some of the machine-readable instructions of FIG. 10 and/or other desired operations. The logic gate circuitry 1308 shown in FIG. 13 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 1308 to enable configuration of the electrical structures and/or the logic gates to form circuits to perform desired operations/functions. The logic gate circuitry 1308 may include other electrical structures such as look-up tables (LUTs), registers (e.g., flip-flops or latches), multiplexers, etc.

The configurable interconnections 1310 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 1308 to program desired logic circuits.

The storage circuitry 1312 of the illustrated example is structured to store result(s) of the one or more of the operations performed by corresponding logic gates. The storage circuitry 1312 may be implemented by registers or the like. In the illustrated example, the storage circuitry 1312 is distributed amongst the logic gate circuitry 1308 to facilitate access and increase execution speed.

The example FPGA circuitry 1300 of FIG. 13 also includes example dedicated operations circuitry 1314. In this example, the dedicated operations circuitry 1314 includes special purpose circuitry 1316 that may be invoked to implement commonly used functions to avoid the need to program those functions in the field. Examples of such special purpose circuitry 1316 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 1300 may also include example general purpose programmable circuitry 1318 such as an example CPU 1320 and/or an example DSP 1322. Other general purpose programmable circuitry 1318 may additionally or alternatively be present such as a GPU, an XPU, etc., that can be programmed to perform other operations.

Although FIGS. 12 and 13 illustrate two example implementations of the programmable circuitry 1112 of FIG. 11, many other approaches are contemplated. For example, FPGA circuitry may include an on-board CPU, such as one or more of the example CPU 1320 of FIG. 12. Therefore, the programmable circuitry 1112 of FIG. 11 may additionally be implemented by combining at least the example microprocessor 1200 of FIG. 12 and the example FPGA circuitry 1300 of FIG. 13. In some such hybrid examples, one or more cores 1202 of FIG. 12 may execute a first portion of the machine-readable instructions represented by the flowchart of FIG. 10 to perform first operation(s)/function(s), the FPGA circuitry 1300 of FIG. 13 may be configured and/or structured to perform second operation(s)/function(s) corresponding to a second portion of the machine-readable instructions represented by the flowchart of FIG. 10, and/or an ASIC may be configured and/or structured to perform third operation(s)/function(s) corresponding to a third portion of the machine-readable instructions represented by the flowchart of FIG. 10.

It should be understood that some or all of the circuitry of FIG. 2 may, thus, be instantiated at the same or different times. For example, same and/or different portion(s) of the microprocessor 1200 of FIG. 12 may be programmed to execute portion(s) of machine-readable instructions at the same and/or different times. In some examples, same and/or different portion(s) of the FPGA circuitry 1300 of FIG. 13 may be configured and/or structured to perform operations/functions corresponding to portion(s) of machine-readable instructions at the same and/or different times.

In some examples, some or all of the circuitry of FIG. 2 may be instantiated, for example, in one or more threads executing concurrently and/or in series. For example, the microprocessor 1200 of FIG. 12 may execute machine-readable instructions in one or more threads executing concurrently and/or in series. In some examples, the FPGA circuitry 1300 of FIG. 13 may be configured and/or structured to carry out operations/functions concurrently and/or in series. Moreover, in some examples, some or all of the circuitry of FIG. 2 may be implemented within one or more virtual machines and/or containers executing on the microprocessor 1200 of FIG. 12.

In some examples, the programmable circuitry 1112 of FIG. 11 may be in one or more packages. For example, the microprocessor 1200 of FIG. 12 and/or the FPGA circuitry 1300 of FIG. 13 may be in one or more packages. In some examples, an XPU may be implemented by the programmable circuitry 1112 of FIG. 11, which may be in one or more packages. For example, the XPU may include a CPU (e.g., the microprocessor 1200 of FIG. 12, the CPU 1320 of FIG. 13, etc.) in one package, a DSP (e.g., the DSP 1322 of FIG. 13) in another package, a GPU in yet another package, and an FPGA (e.g., the FPGA circuitry 1300 of FIG. 13) in still yet another package.

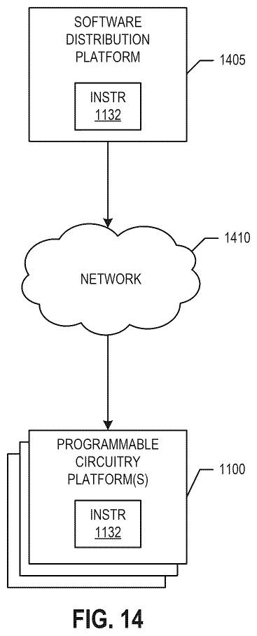

A block diagram illustrating an example software distribution platform 1405 to distribute software such as the example machine-readable instructions 1132 of FIG. 11 to other hardware devices (e.g., hardware devices owned and/or operated by third parties from the owner and/or operator of the software distribution platform) is illustrated in FIG. 14. The example software distribution platform 1405 may be implemented by any computer server, data facility, cloud service, etc., capable of storing and transmitting software to other computing devices. The third parties may be customers of the entity owning and/or operating the software distribution platform 1405. For example, the entity that owns and/or operates the software distribution platform 1405 may be a developer, a seller, and/or a licensor of software such as the example machine-readable instructions 1132 of FIG. 11. The third parties may be consumers, users, retailers, OEMs, etc., who purchase and/or license the software for use and/or re-sale and/or sub-licensing. In the illustrated example, the software distribution platform 1405 includes one or more servers and one or more storage devices. The storage devices store the machine-readable instructions 1132, which may correspond to the example machine-readable instructions of FIG. 10, as described above. The one or more servers of the example software distribution platform 1405 are in communication with an example network 1410, which may correspond to any one or more of the Internet and/or any of the example networks described above. In some examples, the one or more servers are responsive to requests to transmit the software to a requesting party as part of a commercial transaction. Payment for the delivery, sale, and/or license of the software may be handled by the one or more servers of the software distribution platform and/or by a third-party payment entity. The servers enable purchasers and/or licensors to download the machine-readable instructions 1132 from the software distribution platform 1405. For example, the software, which may correspond to the example machine-readable instructions of FIG. 10, may be downloaded to the example programmable circuitry platform 1100, which is to execute the machine-readable instructions 1132 to implement the optical inspection circuitry 102. In some examples, one or more servers of the software distribution platform 1405 periodically offer, transmit, and/or force updates to the software (e.g., the example machine-readable instructions 1132 of FIG. 11) to ensure improvements, patches, updates, etc., are distributed and applied to the software at the end user devices. Although referred to as software above, the distributed “software” could alternatively be firmware.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that detect transparent flux with visible light. Disclosed systems, apparatus, articles of manufacture, and methods include an optical system capable of detecting clear flux through quantification of tackiness and/or surface energy. Additionally, disclosed systems, apparatus, articles of manufacture, and methods include an optical system capable of detecting clear flux through detection classes (e.g., attenuation signatures) and configured parameters entered via an interface (e.g., the GUI 300 if FIG. 3).

Examples disclosed herein include an optical inspection system that can return values for pulling of clear flux (e.g., the ability of clear flux to anchor a component in place), whether there is insufficient coverage of a surface by clear flux (e.g., there is less than a threshold amount of flux on the surface), whether there is sufficient coverage of a surface by clear flux (e.g., there is a threshold amount of flux on the surface), etc. Example clear flux detection disclosed herein is systematic. For example, example clear flux inspection disclosed herein facilitates the systematic and predictable use of clear flux in manufacturing processes. As such, example clear flux inspection disclosed herein facilitates removal of oxide from the surface of solder balls, solder pads, and copper pillars during a manufacturing process in a monetarily inexpensive manner.

Additionally, example clear flux inspection disclosed herein facilitates the anchoring of components (e.g., solder balls, dies, patch substrates, etc.) during conveyance of components on an assembly link in a monetarily inexpensive manner. Examples disclosed herein also include quantifying surface energy and flux tackiness. As such, examples disclosed herein can be utilized to develop a flux material and/or a substrate surface energy library for an industrial environment (e.g., a factory). Examples disclosed herein are scalable across assembly equipment and/or tool sets (e.g., ball attach, chip attach, solder thermal interface material (TIM) attach, etc.)

Furthermore, examples disclosed herein are scalable across inspection tools across multiple industries where clear flux is used for soldering and/or reflow such as the semiconductor industry, the automotive industry, the aerospace industry, the industrial equipment industry, etc. Examples disclosed herein also facilitate classification of multiple process results for clear flux application (e.g., pulling, insufficient coverage, sufficient coverage, attenuation, etc.) to ensure quality and/or to mitigate the effects of process issues.

For example, example flux detection disclosed herein can be performed in-line with a manufacturing process. As such, inspection is not limited to a human observer viewing a setup unit through an optical microscope to verify expected coverage of sprayed flux on solder balls and/or solder pads. Accordingly, examples disclosed herein detect errors in the application of clear flux to substrates at scale and issue alerts to cause reprocessing of substrates with an unexpected amount of flux (e.g., less than a threshold amount of flux, more than a threshold amount of flux, etc.).

Additionally, by facilitating the in-line use of clear flux, examples disclosed herein facilitate improved cleanability of solder resist openings (e.g., via increased acid content of clear flux) which also reduces chances of non-wet defects. Furthermore, by facilitating the in-line use of clear flux, examples disclosed herein avoid using solder paste including metal loading. As such, examples disclosed herein reduce the chance of BGA pins from sticking by avoiding the use of solder paste. Additionally, the use of solder paste increase chances of solder ball bridging during reflow. As such, examples disclosed herein reduce the change of solder ball bridging by avoiding the use of solder paste.

By facilitating the use of clear flux, examples disclosed herein also improve formation of joints during conveyance and improve cleanability. Additionally, disclosed systems, apparatus, articles of manufacture, and methods improve the efficiency of using a computing device by increasing process margins and/or enhancing yield of electronics manufacturing processes. Disclosed systems, apparatus, articles of manufacture, and methods are accordingly directed to one or more improvement(s) in the operation of a machine such as a computer or other electronic and/or mechanical device.

Example methods, apparatus, systems, and articles of manufacture to detect transparent flux with visible light are disclosed herein. Further examples and combinations thereof include the following:

Example 1 includes an apparatus comprising interface circuitry to communicate with an image sensor, machine-readable instructions, and programmable circuitry to at least one of instantiate or execute the machine-readable instructions to cause the image sensor to capture reflected light off of a substrate, the reflected light being visible, and based on a level of attenuation of the reflected light relative to projected light projected onto the substrate, determine at least one of a presence or a property of transparent flux on the substrate.

Example 2 includes the apparatus of example 1, wherein the substrate corresponds to at least one of a semiconductor die or an integrated circuit package substrate.

Example 3 includes the apparatus of any of examples 1 or 2, wherein the programmable circuitry is to, based on the property satisfying a threshold value, flag the substrate as including a threshold amount of the transparent flux.

Example 4 includes the apparatus of any of examples 1 or 2, wherein the programmable circuitry is to, based on the property of the transparent flux not satisfying a threshold value, flag the substrate for reprocessing to adjust an amount of the transparent flux on the substrate.

Example 5 includes the apparatus of any of examples 1, 2, 3, or 4, wherein the programmable circuitry is to determine the property of the transparent flux based on the level of attenuation of the reflected light and at least one of a tackiness of the transparent flux, a surface energy of the substrate, or a temperature of the transparent flux.

Example 6 includes the apparatus of any of examples 1, 2, 3, 4, or 5, wherein the image sensor includes a line-scan image sensor.

Example 7 includes the apparatus of any of examples 1, 2, 3, 4, 5, or 6, wherein the reflected light includes a wavelength between 360 and 750 nanometers.

Example 8 includes a non-transitory machine-readable storage medium comprising machine-readable instructions to cause programmable circuitry to at least cause an image sensor to capture reflected light off of a substrate, the reflected light being visible, and based on a level of attenuation of the reflected light relative to projected light projected onto the substrate, determine at least one of a presence or a property of transparent flux on the substrate.

Example 9 includes the non-transitory machine-readable storage medium of example 8, wherein the substrate corresponds to at least one of a semiconductor die or an integrated circuit package substrate.

Example 10 includes the non-transitory machine-readable storage medium of any of examples 8 or 9, wherein the machine-readable instructions cause the programmable circuitry to, based on the property satisfying a threshold value, flag the substrate as including a threshold amount of the transparent flux.

Example 11 includes the non-transitory machine-readable storage medium of any of examples 8 or 9, wherein the machine-readable instructions cause the programmable circuitry to, based on the property of the transparent flux not satisfying a threshold value, flag the substrate for reprocessing to adjust an amount of the transparent flux on the substrate.

Example 12 includes the non-transitory machine-readable storage medium of any of examples 8, 9, 10, or 11, wherein the machine-readable instructions cause the programmable circuitry to determine the property of the transparent flux based on the level of attenuation of the reflected light and at least one of a tackiness of the transparent flux, a surface energy of the substrate, or a temperature of the transparent flux.

Example 13 includes the non-transitory machine-readable storage medium of any of examples 8, 9, 10, 11, or 12, wherein the image sensor includes a line-scan image sensor.

Example 14 includes the non-transitory machine-readable storage medium of any of examples 8, 9, 10, 11, 12, or 13, wherein the reflected light includes a wavelength between 360 and 750 nanometers.

Example 15 includes a method comprising capturing reflected light off of a substrate, the reflected light being visible, and based on a level of attenuation of the reflected light relative to projected light projected onto the substrate, determining, by executing an instruction with programmable circuitry, at least one of a presence or a property of transparent flux on the substrate.

Example 16 includes the method of example 15, wherein the substrate corresponds to at least one of a semiconductor die or an integrated circuit package substrate.

Example 17 includes the method of any of examples 15 or 16, further including, based on the property satisfying a threshold value, flagging the substrate as including a threshold amount of the transparent flux.

Example 18 includes the method of any of examples 15 or 16, further including, based on the property of the transparent flux not satisfying a threshold value, flagging the substrate for reprocessing to adjust an amount of the transparent flux on the substrate.

Example 19 includes the method of any of examples 15, 16, 17, or 18, further including determining the property of the transparent flux based on the level of attenuation of the reflected light and at least one of a tackiness of the transparent flux, a surface energy of the substrate, or a temperature of the transparent flux.

Example 20 includes the method of any of examples 15, 16, 17, 18, or 19, wherein the reflected light includes a wavelength between 360 and 750 nanometers.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus comprising:
interface circuitry to communicate with an image sensor;
machine-readable instructions; and
programmable circuitry to at least one of instantiate or execute the machine-readable instructions to:
cause the image sensor to capture reflected light off of a substrate, the reflected light being visible; and
based on a level of attenuation of the reflected light relative to projected light projected onto the substrate, determine at least one of a presence or a property of transparent flux on the substrate.

2. The apparatus of claim 1, wherein the substrate corresponds to at least one of a semiconductor die or an integrated circuit package substrate.

3. The apparatus of claim 1, wherein the programmable circuitry is to, based on the property satisfying a threshold value, flag the substrate as including a threshold amount of the transparent flux.

4. The apparatus of claim 1, wherein the programmable circuitry is to, based on the property of the transparent flux not satisfying a threshold value, flag the substrate for reprocessing to adjust an amount of the transparent flux on the substrate.

5. The apparatus of claim 1, wherein the programmable circuitry is to determine the property of the transparent flux based on the level of attenuation of the reflected light and at least one of a tackiness of the transparent flux, a surface energy of the substrate, or a temperature of the transparent flux.

6. The apparatus of claim 1, wherein the image sensor includes a line-scan image sensor.

7. The apparatus of claim 1, wherein the reflected light includes a wavelength between 360 and 750 nanometers.

8. A non-transitory machine-readable storage medium comprising machine-readable instructions to cause programmable circuitry to at least:
cause an image sensor to capture reflected light off of a substrate, the reflected light being visible; and
based on a level of attenuation of the reflected light relative to projected light projected onto the substrate, determine at least one of a presence or a property of transparent flux on the substrate.

9. The non-transitory machine-readable storage medium of claim 8, wherein the substrate corresponds to at least one of a semiconductor die or an integrated circuit package substrate.

10. The non-transitory machine-readable storage medium of claim 8, wherein the machine-readable instructions cause the programmable circuitry to, based on the property satisfying a threshold value, flag the substrate as including a threshold amount of the transparent flux.

11. The non-transitory machine-readable storage medium of claim 8, wherein the machine-readable instructions cause the programmable circuitry to, based on the property of the transparent flux not satisfying a threshold value, flag the substrate for reprocessing to adjust an amount of the transparent flux on the substrate.

12. The non-transitory machine-readable storage medium of claim 8, wherein the machine-readable instructions cause the programmable circuitry to determine the property of the transparent flux based on the level of attenuation of the reflected light and at least one of a tackiness of the transparent flux, a surface energy of the substrate, or a temperature of the transparent flux.

13. The non-transitory machine-readable storage medium of claim 8, wherein the image sensor includes a line-scan image sensor.

14. The non-transitory machine-readable storage medium of claim 8, wherein the reflected light includes a wavelength between 360 and 750 nanometers.

15. A method comprising:
capturing reflected light off of a substrate, the reflected light being visible; and
based on a level of attenuation of the reflected light relative to projected light projected onto the substrate, determining, by executing an instruction with programmable circuitry, at least one of a presence or a property of transparent flux on the substrate.

16. The method of claim 15, wherein the substrate corresponds to at least one of a semiconductor die or an integrated circuit package substrate.

17. The method of claim 15, further including, based on the property satisfying a threshold value, flagging the substrate as including a threshold amount of the transparent flux.

18. The method of claim 15, further including, based on the property of the transparent flux not satisfying a threshold value, flagging the substrate for reprocessing to adjust an amount of the transparent flux on the substrate.

19. The method of claim 15, further including determining the property of the transparent flux based on the level of attenuation of the reflected light and at least one of a tackiness of the transparent flux, a surface energy of the substrate, or a temperature of the transparent flux.

20. The method of claim 15, wherein the reflected light includes a wavelength between 360 and 750 nanometers.
